(19) United States
(12) Patent Application Publication
(10) Pub. No.: US 2022/0223771 A1
(43) Pub. Date: Jul. 14, 2022

(54) OPTOELECTRONIC COMPONENT, PIXELS, DISPLAY ASSEMBLY, AND METHOD

(71) Applicant: OSRAM Opto Semiconductors GmbH, Regensburg (DE)

(72) Inventors: Martin BEHRINGER, Regensburg (DE); Peter BRICK, Regensburg (DE); Hubert HALBRITTER, Dietfurt-Toeging (DE); Laura KREINER, Regensburg (DE); Tansen VARGHESE, Regensburg (DE); Berthold HAHN, Hemau - Hohenschambach (DE); Bruno JENTZSCH, Regensburg (DE); Christopher WIESMANN, Barbing (DE); Jens MUELLER, Regensburg (DE); Christian MUELLER, Deuerling (DE)

(21) Appl. No.: 17/595,298

(22) PCT Filed: Mar. 30, 2020
(86) PCT No.: PCT/EP2020/058997

§ 371 Date: Nov. 12, 2021

(30) Foreign Application Priority Data
May 14, 2019 (DE) 10 2019 112 604.5
May 23, 2019 (DE) 10 2019 113 792.6
Oct. 29, 2019 (DE) 10 2019 129 209.3
Nov. 21, 2019 (DE) 10 2019 131 506.9
Jan. 29, 2020 (EP) PCT/EP2020/052191

(51) Int. Cl. H01L 33/60; H01L 25/075; H01L 33/50; H01L 27/15; H01L 27/18

(52) U.S. Cl. CPC H01L 33/60; H01L 25/0753; H01L 33/30; H01L 27/156; H01L 27/18; H01L 33/507

(57) ABSTRACT

An optoelectronic component comprising at least one semiconductor element having an active region adapted to generate light is proposed. the device comprises a dielectric filter disposed above a first major surface of the at least one semiconductor element and adapted to transmit light only in pre-planar directions, and a reflective material disposed on at least one side surface of the at least one semiconductor element and on at least one side surface of the dielectric filter.

This patent application claims the priority of German application DE 10 2019 112 604.5 dated May 14, 2019, the priority of German application 10 2019 113 792.6 dated May 23, 2019, the priority of German application 10 2019 129 209.3 dated Oct. 29, 2019, the priority of German application 10 2019 131 506.9 dated Nov. 21, 2019, and the priority of international application PCT/EP2020/052191 dated Jan. 29, 2020, the disclosures of which are hereby incorporated by reference.

The invention relates to an optoelectronic component and a pixel comprising an optoelectronic component. The invention further relates to a display device and methods of manufacturing the same.

### BACKGROUND

In many displays and also other applications, optoelectronic components are built monolithically. This means that instead of placing individual components on a board or backplane, optoelectronic components are integrated into a substrate so that they can be controlled individually. On the one hand, this allows the size to be reduced, but another advantage is a reduction in transfer processes and soldering steps. In addition, such monolithic modules can be easily scaled, i.e. scaled both in the size of the individual components and in the size of the module. Components can be arranged in a freely definable matrix. These scaling effects are particularly useful in the production of mass products.

The different applications require, among other things, different radiation characteristics. In some applications the optoelectronic components should have a Lambertian radiation pattern, in other applications the radiation should be as directional as possible.

In the case of a monolithic structure, control electronics can be integrated in the substrate in which the optoelectronic components are also manufactured. On the other hand, circuits and optoelectronic components can also be manufactured separately and then joined together. In this case, care must be taken to ensure good positioning.

This application addresses a number of issues for monolithic displays, including redundancy in the event of failure of one optoelectronic component, radiation patterns and driving.

### SUMMARY OF THE INVENTION

One aspect deals with an improvement of the radiation characteristics of a LED to which a dielectric filter with additional reflecting sides is applied. An optoelectronic component, in particular an LED according to a first aspect of the present disclosure comprises at least a semiconductor element, a dielectric filter, and a reflective material.

The at least one semiconductor element includes an active region configured to generate light. In particular, it may be configured as a vertical or horizontal LED. Measures for increasing the efficiency of the device are possible. Furthermore, the at least one semiconductor element comprises a first main surface, a second main surface opposite the first main surface, and at least one side surface extending between the two main surfaces. For example, the at least one semiconductor element may have three or four or more side surfaces. However, it is also conceivable that the at least one semiconductor element has round major surfaces and therefore has only one side surface.

The dielectric filter is disposed above the first major surface of the at least one semiconductor element, and is configured to transmit or pass only light entering the dielectric filter in pre-planar directions.

For example, the dielectric filter may be configured to transmit light only in a predetermined angular cone. The angular cone is oriented with its axis perpendicular to the first major surface of the at least one semiconductor element. The angle between the lateral surface or surface lines of the cone and the axis of the cone, i.e. the half aperture angle of the cone, may have a predetermined value. For example, the half opening angle of the cone may be at most 5° or at most 15° or at most 30° or at most 60°. Light components that enter the dielectric filter from the semiconductor element with an angle that is within the predetermined angular cone are transmitted, and the remaining light components are substantially not transmitted and are reflected back into the semiconductor element, for example. This allows a high directionality of the light emitted by the optoelectronic component.

The dielectric filter may be configured such that the angular cone has a very small aperture angle, resulting in substantially only light exiting the semiconductor element perpendicular to the first major surface being transmitted by the dielectric filter.

In one aspect, the dielectric filter may be constructed from a stack of dielectric layers deposited by coating on the semiconductor element, and in particular may have high transmission. For example, the dielectric layers in the stack may have alternating low and high refractive index. For example, Nb2O5, TiO2, ZrO2, HfO2, Al2O3, Ta2O5 or ZnO may be used as the material for the high refractive index dielectric layers. For the dielectric layers with low refractive index, SiO2, SiN, SiON or MgF2 can be used, for example. The stack of dielectric layers with alternating high and low refractive index may be formed as a Bragg filter. Further, the dielectric filter may be a photonic crystal.

The reflective material is deposited on the one or more side surfaces of the at least one semiconductor element and the dielectric filter. It may be provided that the reflective material covers at least one or more or all of the side surfaces of the at least one semiconductor element. Similarly, the reflective material may cover at least one or more or all of the side surfaces of the dielectric filter. In one embodiment, the reflective material completely laterally surrounds both the at least one semiconductor element and the dielectric filter.

The reflective material may be reflective to light emitted from the at least one semiconductor element, or at least a wavelength range of such light. Consequently, light emitted through the side surfaces of the at least one semiconductor element or the dielectric filter is reflected back, thereby increasing the efficiency of the optoelectronic component.

Several components may also be provided. These in turn have one or more monolithically constructed semiconductor elements, each of which has the properties described above. A dielectric filter is arranged on each of the semiconductor elements. In addition, the semiconductor elements are surrounded by the reflective material. Additionally or alternatively, a plurality of devices with their semiconductor elements may be surrounded by such a mirror. For example, such an embodiment allows to provide redundancy, so that in case of failure of a semiconductor element, a redundant semiconductor element can take over the function. For example, the semiconductor elements may be arranged in an array, i.e. a regular arrangement of a monolithic display.

The optoelectronic component may be included in a display, i.e., a display device. Each of the semiconductor elements may represent or constitute a pixel of the display. Further, each of the semiconductor elements may represent a sub-pixel of a pixel, each pixel being formed of a plurality of sub-pixels emitting, for example, light having red, green and blue colors.

Due to the reflective material surrounding the individual semiconductor elements and the respective dielectric filters laterally in each case, a high contrast between adjacent pixels is achieved. Furthermore, a high pixel density is possible. According to one embodiment, the semiconductor elements are implemented as LEDs. An LED has small lateral extensions in the light emitting plane, in particular in the range of 140 μm to 750 μm. In contrast to separate LEDs, the components in a monolithic array each form a self-contained unit. The light emitted by the semiconductor elements can be, for example, light in the visible range, ultraviolet (UV) light and/or infrared (IR) light.

In addition to displays, the optoelectronic component according to the first aspect of the application can also be used, for example, in AR (augmented reality) applications or in other applications for pixelated arrays or pixelated light sources.

According to one embodiment, at least one or more or all of the side surfaces of the at least one semiconductor element extend obliquely at the level of the active region. This means that at least a part of the respective side surface encloses an angle with the first main surface of the at least one semiconductor element which is not equal to 90° and in particular is smaller than 90°. The at least one semiconductor element may be bevelled over its entire height or only partially, the active region being in any case located in the bevelled region. The completely or partially bevelled side surfaces may form an interface with an insulating layer having a low refractive index. Light emitted in the horizontal direction is reflected towards the surface of the component by the bevelled side surfaces.

The at least one semiconductor element may have a first electrical terminal and a second electrical terminal. For example, one terminal may represent a cathode and the other terminal may represent an anode. Further, the reflective material may be electrically conductive and electrically coupled to the first terminal of the at least one semiconductor element. In particular, the first terminal may be connected to an n-doped region of the at least one semiconductor element. Consequently, the reflective material both provides optical separation between adjacent pixels and also provides electrical contact to the at least one semiconductor element.

If several optoelectronic components with a plurality of semiconductor elements are provided, the reflective as well as electrically conductive material surrounding the respective semiconductor elements can be interconnected, which makes it possible to drive the first terminals of the semiconductor elements together externally. In this case, the second terminals of the semiconductor elements may be individually drivable, for example via the bottom side of the semiconductor elements. Since only one contact needs to be defined with a good resolution, this embodiment is advantageous in manufacturing and also facilitates the manufacturing of very small pixels where the area would not be sufficient to provide two separate contacts on the underside of the chip. The reflective material may be or include, for example, a metal and may be electrodeposited.

A reflective layer may be disposed below the second major surface of the at least one semiconductor element. As a result, light exiting through the second major surface is reflected back into the semiconductor element and exits completely through the top surface from the optoelectronic component. Further, the reflective layer may be electrically conductive and coupled to the second terminal of the at least one semiconductor element. For example, the second terminal may be coupled to a p-doped region of the at least one semiconductor element. Consequently, in addition to its reflective properties, the reflective layer also serves to provide an electrical contact with the at least one semiconductor element. It may be provided that the second terminal of each semiconductor element is individually controllable.

The reflective layer may or may not be made of the same material as the reflective material. For example, a metal can be used for the reflective layer.

Alternatively to the embodiment described above, the reflective layer may be electrically insulating and one or more electrically conductive layers may be arranged above and/or below the reflective layer, in particular coupled to the second terminal of the at least one semiconductor element. In this case, the reflective layer may be, for example, a dielectric mirror and may in particular be arranged above a metal layer. Electrical contact is then made via a feedthrough through the dielectric layer or via a side surface of the dielectric layer. Furthermore, an electrically conductive as well as transparent layer may be arranged above the reflective layer, i.e. between the at least one semiconductor element and the reflective layer. For example, indium tin oxide (ITO) can be used as the material for the electrically conductive and transparent layer.

According to one embodiment, a silver mirror is arranged below the electrically conductive and transparent layer, for example of indium tin oxide, and the dielectric mirror. Alternatively, only an electrically conductive and transparent layer, for example of indium tin oxide, and a silver mirror may be arranged below the at least one semiconductor element.

An electrically insulating first material may be disposed between the reflective material and the reflective layer. The electrically insulating first material may further be in direct contact with one or more of the side surfaces of the at least one semiconductor element, in particular with the beveled portion of the side surfaces. Further, the electrically insulating first material may have a lower refractive index than the at least one semiconductor element, in particular than the at least one semiconductor element in the region of the interface with the electrically insulating first material. Consequently, the electrically insulating first material provides electrical insulation between the first and second terminals of the at least one semiconductor element. Furthermore, light may be reflected back at the interface between the at least one semiconductor element and the electrically insulating first material due to the refractive index contrast.

The electrically insulating first material may be, for example, SiO2 and deposited by a deposition process, in particular a vapour deposition process, for example using TEOS (tetraethyl orthosilicate), or another process, for example based on silane, in order to fill high aspect ratios.

Between the at least one semiconductor element and the dielectric filter, i.e. on the first main surface of the at least one semiconductor element, a layer with a roughened surface may be arranged, which is designed to deflect light in other spatial directions or to scatter light. The layer may have a Lambertian radiation characteristic. Furthermore, the layer can be designed in such a way that light components with angles beyond the limiting angle for total reflection are deflected, so that in principle all components can be decoupled and do not remain “trapped” in the component.

The layer described above may, for example, comprise a randomly or deterministically structured semiconductor surface. The surface may have a roughened structure with sloping edges, the roughened structure having a height of at most a few 100 nm. The roughened structure may be produced, for example, by etching.

It is further possible to dispense with the layer described above and instead roughen the first main surface of the at least one semiconductor element. For this purpose, for example, a random or deterministic topology may be etched into the first main surface, in particular to achieve a Lambertian radiation pattern. The roughened first major surface of the at least one semiconductor element may have the same properties as the roughened surface of the layer described above.

On the roughened surface of the at least one semiconductor element or the layer arranged thereabove, a further layer, for example of SiO2, may be deposited which has a different refractive index to the underlying layer and also has a flat upper surface. This additional layer allows the dielectric filter to be deposited due to its flat upper surface, and at the same time it maintains the functionality of the underlying roughened surface due to the difference in refractive index.

The lateral extent of a pixel in the range of, for example, 140 μm to 750 μm allows the at least one semiconductor element to have a height in the range of a few μm. In particular, the at least one semiconductor element may have a height in the range of 3 μm to 30 μm.

As described further above, a device may include a plurality of optoelectronic components which may have the embodiments described in the present application. Each of the semiconductor elements of a device may be completely surrounded laterally by the reflective material, together with the associated dielectric filter and the reflective layer disposed beneath the respective semiconductor element. According to one embodiment, the semiconductor elements are arranged in an array with adjacent semiconductor elements being separated from each other by the reflective material. Consequently, the reflective material forms a grid and adjacent semiconductor elements are separated from each other only by the grid.

Furthermore, if the reflective material is electrically conductive, the first terminals of all semiconductor elements may be connected to a common external terminal via the reflective material. The second terminals of the semiconductor elements may be individually drivable.

According to an alternative embodiment, the plurality of semiconductor elements each laterally surrounded by the reflective material are arranged side by side with an electrically insulating second material arranged between adjacent semiconductor elements. For example, the electrically insulating second material may be a potting material.

The reflective material may also be electrically conductive in this embodiment. To connect the first terminals of the semiconductor elements to a common external terminal, conductive traces may extend above and/or below and/or within the electrically insulating second material connecting the first terminals of the semiconductor elements to the common external terminal. The second terminals of the semiconductor elements may be individually drivable.

For driving, another substrate can be provided, which is placed with contacts so as to connect the terminals of the semiconductor device.

A method according to a second aspect of the present application is for manufacturing an optoelectronic component. The method comprises providing at least one semiconductor element having an active region configured to generate light, and disposing a dielectric filter above a first major surface of the at least one semiconductor element. The dielectric filter is configured to transmit light only in pre-planar directions. Further, a reflective material is disposed or deposited on at least one side surface of the at least one semiconductor element and on at least one side surface of the dielectric filter.

The method of manufacturing an optoelectronic component according to the second aspect of the application may comprise the above-described embodiments of the optoelectronic component according to these aspects of the application.

In the following, aspects of processing and methods for manufacturing an LED or a display or module will be considered in more detail. However, as already explained in the foregoing, aspects of processing also include aspects of semiconductor structures or materials and vice versa. In this respect, the following aspects can be combined with the previous ones without further ado.

Due to the manufacturing process and the extremely small dimensions of individual optical elements, it can sometimes happen that individual pixel elements from the large number of pixels in a display are defective. This problem has a greater impact on monolithic display modules, as defects or variations in the manufacturing process are difficult to repair or rectify due to integration. If the defect density becomes too high, the entire module must be replaced. Particularly with monolithic displays, individual defective pixels cannot be replaced.

Known solutions attempt to compensate for a failed pixel, for example, by setting surrounding or adjacent pixels to a higher luminosity, thereby at least partially compensating for the missing light of the defective pixel. Since in many cases the replacement or repair of these defective pixels does not appear to be economically or procedurally feasible, it is desirable to still be able to use a manufactured display with sufficiently good quality despite isolated defective pixels.

The aspects described below concerning pixel elements with electrically separated and optically coupled subpixels can compensate for such small defects, so that an improved yield is achieved while maintaining the quality of the displays or display modules. It should be mentioned here that the concept presented here can also be used for the devices described further above, in that the laterally applied material serves as optical and electrical separation, as will be described below.

Thereby, these aspects are based on the consideration to use measures suitable for the prevention of an optical crosstalk. In this respect, the measures proposed in the following are therefore not only suitable for the above task, but a reduction of an optical crosstalk has further advantages if optically active areas are very close to each other, especially in monolithic devices, and a good optical separation is to be achieved. In very densely packed monolithic arrays or displays or display modules, clean optical separation between the pixels is necessary to prevent the emitted light of an optically active element, an LED, from radiating into an area of an adjacent pixel. To reduce optical crosstalk, trenches, or more generally, optically separating structures are often provided between two LEDs. While on the one hand optical crosstalk is to be suppressed in order to achieve a sufficiently good high-contrast image quality, the failure of a pixel may be more noticeable as a result.

Therefore, an optical pixel element for generating a pixel of a display is proposed, which is formed by at least two subpixels. According to an example, 2, 4, 6, 9, 12 or 16 subpixels are provided per pixel element. In other words, redundancy is provided here, wherein the two subpixels receive the same driving information and are implemented for the same wavelength, for example. Thus, if one subpixel of these at least two subpixels fails, the pixel element can still emit the light of that wavelength. According to an example, a luminosity of a subpixel is adjustable to compensate for the missing amount of light of a failed subpixel. According to an example, the subpixels are implemented as so-called arrays. For example, if a pixel element is embodied as a rectangular structure, the subpixels within the structure of the pixel element are formed by dividing them again into arrays. Each of these subpixels in a field can be controlled independently of the subpixels in other fields.

The subpixels each have an optical emitter area. This is intended to ensure that each subpixel is individually controllable and self-sufficiently functional. The emitter region comprises a p-n junction, one or more quantum well structures or other active layers intended for light generation. The emitter region is provided with a contact on its underside, which is provided for connection to a control unit or drive electronics.

The drive electronics are configured to electrically control the individual pixel elements as well as the individual subpixels. For example, the drive electronics or the control device may be configured to detect a defect of a subpixel and to subsequently no longer use the defective subpixel. Further, according to an example, the drive electronics may be configured to drive an adjacent subpixel such that a luminosity is increased such that a luminosity of an adjacent failed subpixel is compensated. For this purpose, a memory unit that stores an operating state of a subpixel may be provided in the drive electronics, for example. In other words, a central detection of subpixels detected as defective may take place here in order to perform defect compensation, if necessary, by luminosity adjustment or switching on or off adjacent subpixels or pixel elements. In another embodiment, for example, the time that a subpixel is active may be increased to compensate for a failed subpixel. On the other hand, if all subpixels are functional, the drive circuit may also drive them all with reduced luminosity, reduced time duration, or multiplexed in each case. Using functional subpixels with lower current and/or time duration may increase the lifetime of the subpixels.

In order to separate two adjacent subpixels from each other within a pixel element, a subpixel separating element is provided. Thereby, the subpixel separating element has an electrically separating effect with respect to the driving of the respective emitter chips or the driving of the subpixels. In other words, this subpixel separating element may be of the type that prevents electrical interaction between the emitter chips of the adjacent subpixels.

In particular, due to the use of semiconductors and the small distances between the emitter areas of the individual subpixels in the [μm] range, driving an emitter chip may have secondary electrical or electromagnetic effects on spatially adjacent or surrounding areas. This may, in some circumstances, result in an adjacent emitter chip also being activated when driving a primary emitter chip. The subpixel separation element is therefore designed to prevent electrical or optical crosstalk to the adjacent subpixel and possible activation of the adjacent subpixel.

On the other hand, the subpixel separating element should be designed to optically couple with respect to the emitted light from the emitter chips of the adjacent subpixels, so that the visual impression of individual subpixels being switched off is counteracted. By optically coupling is meant here that light generated by a primary emitter chip or a primary sub-pixel can pass to the adjacent sub-pixel by optical crosstalk. Advantageously, this can prevent the defect in a subpixel from creating a dark dot or dark spot. Instead, light from the adjacent subpixel can cross over and be emitted in the direction of emission, starting from the subpixel that is defective per se. This can advantageously compensate for a visible effect of a defective subpixel. Therefore, the subpixel separating element does not have a separating effect visually and should not be achieved.

This is advantageous if one subpixel fails. Due to the lack of optical separation, the pixel is still perceived as a whole and there is no different visual impression than when both subpixels are active. In one aspect, the subpixel separation element may be implemented such that it electrically separates but does not optically or even optically promote crosstalk. In one embodiment, the subpixel separating element is drawn only to just before the active layer of the two subpixels or into the active layer. In other words, the subpixel separation element electrically separates two subpixel elements otherwise connected via common layers.

In one aspect, the subpixels have a common epitaxial layer. In many cases, pixel elements or entire displays are constructed such that a common layer or multiple superimposed layers are grown to interconnect a plurality of subpixels and/or pixel elements. This may also be used, for example, to provide a common electrical contact or connection. According to one example, the epitaxial layer comprises Group III elements gallium, indium or aluminum, and Group V elements nitrogen, arsenic or phosphorus, or combinations thereof or material systems comprising said elements. This can, among other things, influence a color and wavelength of the emitted light of a light-emitting diode. The epitaxial layer can also have active semiconductor layers, for example a p-doped region and an n-doped region including the active boundary regions.

For example, an emitter chip is arranged on a first side of the epitaxial layer transverse to a longitudinal extension of an epitaxial layer plane. Light from the emitter chip is then emitted transversely through the epitaxial layer toward a second opposite side of the epitaxial layer and emitted therefrom. The subpixel separation element extends in a trench-like manner into the epitaxial layer transversely to the epitaxial layer plane, starting from the first side of the epitaxial layer at which the emitter chip or the LED is arranged.

In other words, the subpixel separation element is implemented here as a recess, gap, slot or similar structure, which may further be filled with an electrically insulating material. The insulating material should also be optically transparent to facilitate optical crosstalk. Thereby, according to one example, the length of the trench is selected such that drive signals to a subpixel do not electrically crosstalk to a secondary adjacent subpixel of the same pixel. Among other things, such a trench-like structure increases the electrical resistance due to the significantly extended path of the current flow and thus creates an electrical decoupling.

The optical effects concerning the emitted light again concern a region of the epitaxial layer which is further in the middle or further towards the second distant side of the epitaxial layer. Thus, one chooses the depth of the trench in such a way that electrical decoupling is ensured, but on the other hand the trench ends in front of a region of the epitaxial layer in which light can be transmitted between two adjacent subpixels. The emission direction of the emitter chip runs, for example, in the direction across the epitaxial layer in order to allow the light to exit at the opposite second side.

According to one example, the trench extends at a right angle relative to the plane of the epitaxial layer. Assuming this course of the trench, according to another example, a length d1 of the trench is less than a total thickness of the epitaxial layer. Here, it is assumed that the epitaxial layer has an at least approximately equal total thickness over a plurality of pixel elements and sub-pixels. According to another example, the length d1 of the trench between the pixel elements is equal to the thickness of the epitaxial layer. In other words, this means that the trench is continuous from the first side of the epitaxial layer to the second side of the epitaxial layer. According to another example, the trench extends continuously obliquely through the epitaxial layer at an angle between 0 and 90° relative to the epitaxial layer plane.

In one aspect, each pixel element or sub-pixel elements thereof comprises a plurality of semiconductor layers in the form of a layer stack, and further comprising an active layer for generating light. The active layer may comprise quantum wells or another structure prepared to generate light. In one aspect, the one or more layers extend across a plurality of pixels or subpixels. For example, it may be provided that the active layer extends over multiple subpixels of a color.

According to one aspect, the subpixels or pixel elements can be electrically contacted and/or controlled independently of each other. For this purpose, contacts may be provided, for example, on the side of the subpixels remote from an epitaxial layer. These can be, for example, mechanical contacts, solder connections, clamp connections or the like. It is crucial here that the subpixels of the individual subpixels can be contacted and electrically operated without substantial interaction with the adjacent subpixels of the adjacent subpixels. This may be particularly advantageous for a detection of the functional state or operating state of a subpixel, since a diagnostic information may be generated individually for each individual subpixel. It is also convenient to turn individual subpixels on or off without involving adjacent subpixels. This can reduce thermal or other stress on the subpixels at higher intensities, as multiple subpixels can be operated simultaneously at lower intensities.

According to a further aspect, the individual subpixels are contacted via a carrier substrate. On the one hand, the carrier substrate should enable mechanical stability and, on the other hand, simultaneously integrate the fine conductor structures for the individual contacting of the individual subpixels. Further elements such as control electronics or driver circuits may also be integrated in the carrier substrate and in particular in silicon wafers. This can have the same material system, but also a different material system via adaptation layers. In this way, silicon can also be used as the carrier material. As a result, circuits for driving in particular can be easily implemented in this carrier.

According to one example, a brightness of the pixel element can be adjusted by switching individual subpixels off or on. It can be seen as an advantage here that a single switching off or switching on can already enable effective brightness control. This may, for example, significantly simplify a drive electronics or a control unit. According to a further example, a luminosity of one or more subpixels of the pixel element is additionally adjustable. Hereby, a brightness, or in interaction with different wavelengths of the subpixels of the same pixel element, a color spectrum can be more precisely adjusted or calibrated in even finer gradations. An adjustment of the brightness can be done by a PWM control. If a subpixel has failed, an equivalent brightness can still be achieved by extending the PWM control accordingly. Conversely, if the subpixels are intact, the PWM control can be adjusted, allowing the subpixels to be operated at their maximum efficiency and possibly also resulting in lower thermal stress and thus a longer service life.

For example, if eight subpixels are structured in one pixel element, a brightness dynamic of 2∧3 levels is achievable without varying further control variables such as current or ontime. In other words, in this embodiment, a dynamic range can be increased by a factor of 2∧3. This can also limit a complexity of the control electronics and thus corresponding costs.

In a further aspect, a display comprising a plurality of pixel elements as described above and below is proposed. According to one aspect, such a display may be an optical semiconductor display, for example, for applications in the augmented reality field or in the automotive field, where small displays with very high resolutions are used. Similarly, such a display may be used in wearable devices such as smart watches or wearables.

A pixel element separation layer is provided between two adjacent pixel elements. This is designed in such a way that the adjacent pixel elements are electrically separated with respect to the control of the respective pixel elements. Furthermore, the pixel element separation layer is configured to perform optical separation with respect to the light emitted from the pixel elements. Initially, a pixel element separation layer may be understood abstractly as any structure or material that separates two pixel elements from each other. Usually, a plurality of such pixel elements are arranged next to each other in a plane, for example on a carrier surface, and are connected via contacts to drive electronics. In this way, a display can be formed in its entirety.

The electrical and electromagnetic separation is intended to ensure that a pixel element can be driven independently of adjacent pixel elements and that there is minimal or no electrical or electromagnetic interaction, in particular no optical interaction. This is important simply in order to be able to generate each pixel independently for displaying a particular image content on the display. The optical separation, in turn, is necessary to achieve sufficient sharpness and contrast or delineation of the individual pixels from one another on the display.

In one aspect, a plurality of pixel elements have a common epitaxial layer. The pixel element separation layer is trench-like and extends transversely to the epitaxial layer plane in the emission direction of the emitter chips. In other words, the pixel element separation layer is embodied as a trench, slit, slot or similar recess that either contains no solid material or comprises, for example, a reflective or absorbent material. In one example, the pixel separating element is filled with an insulating material in which a mirror layer is incorporated. The insulating material electrically separates two adjacent pixels and the mirror element prevents optical crosstalk. In some embodiments, the mirror element is also provided for or supports collimation of light.

The pixel element separation layer is intended to prevent electrical or electromagnetic signals from being transmitted from one pixel element to another pixel element. At the same time, the pixel element separation layer is configured to achieve that as little or no light as possible is emitted from one pixel element to an adjacent pixel element. In one example, the pixel element separation layer may be formed solely by placing two separated pixel elements adjacent to each other when arranging them, thereby resulting in a corresponding insulating or reflective boundary layer. According to one example, the trench is perpendicular to the epitaxial layer plane, wherein a length of the pixel element separation layer is less than or equal to a thickness of the epitaxial layer.

According to a further aspect, the trench depth of the pixel element separation layer is greater than a trench depth of the sub-pixel separation layer. In particular, this is intended to provide the advantage that the pixel element separation layer provides both electrical and optical separation due to its greater length. In contrast, the shallower trench depth between the subpixels provides only electrical separation, although optical crosstalk is certainly desirable. In some aspects, the depth of the pixel element separation layer extends through and separates the active layer of second adjacent pixels. Additionally, the pixel element separation layer may extend to or just below the radiating surface.

In another aspect, a method for calibrating a pixel element is proposed. This method is based on the idea that, when a display is put into operation, an optimal activation is to be enabled. This may mean, for example, that defective subpixels are to be detected as such and thereafter, if necessary, no further actuation takes place. In this way, for example, error messages or malfunctions can be avoided. Due to the structure of the pixel elements with the subpixels, it can be achieved that each subpixel can be individually controlled and tested.

Therefore, in a first step, a subpixel of a pixel element is driven, for example by a drive electronics or a control unit. In a next step, a detection of a defect information of a subpixel is performed. In other words, the drive electronics may be configured and designed in such a way that a malfunction or a defect is detected. For this purpose, for example, a current intensity can be measured or other electrical variables can be evaluated.

In a further step, the defect information is stored in a memory unit of the control unit. This information can be used, for example, to carry out an optimized control by the control electronics. For example, if a certain luminosity is to be achieved and it is known that a certain subpixel is defective, the drive electronics can drive the neighboring subpixels in a correspondingly differentiated manner, for example in order to compensate for a luminosity. As a result, an amount of light emitted by the pixel element would be exactly or nearly unchanged despite a defective subpixel and would not be noticeable to an observer.

In another aspect of the method, the driving, sensing, and storing is performed sequentially for all individual subpixels of a pixel element. In other words, a drive electronics may be configured to sequentially check all available subpixels via the individual separately addressable emitter chips and thus detect a functional state of the entire pixel element. According to one example, this can be done once when a display is switched on or after a certain period of time has elapsed.

An extension of pixelated or otherwise emitters where optical and electrical crosstalk is reduced is presented in the following concepts.

In conventional monolithic pixel arrays, it is common in some aspects to etch through the active region so as to separate the individual pixels and address them individually. However, the etching process through the active layer causes defects that can lead to increased leakage currents at the edges, on the one hand, and generate additional non-radiative recombination, on the other. As the pixels become smaller, the relative damage area effectively increases. Traditionally, the edge of the etched active region is passivated by various methods. Such techniques include regrowth, insitu passivation layer deposition, diffusion of species to shift the pn junction and increase the band gap around the active region, and wet etch washing to remove as much damage as possible.

According to the proposed principle, a Pixel structure with a material bridge is proposed, which at least still comprises the active layer. This reduces an increased defect density in the area of the active layer.

Thus, an array of optoelectronic pixels or subpixels comprises a respective pixel or subpixel forming an active region between an n-doped layer and a p-doped layer. According to the proposed principle, material of the layer stack from the n-doped side and from the p-doped side is interrupted or removed between two adjacent formed pixels up to or in cladding layers or up to or at least partially in the active region. In this way, material junctions are formed with a maximum thickness dC, whereby electrical and/or optical conductivities in the material junction are reduced.

According to a second aspect, a method of forming an array of optoelectronic pixels or subpixels is proposed in which, in a first step, a full-area layer stack comprising an n-doped layer and a p-doped layer between which an active region suitable for light emission is formed is provided along the array. Subsequently, material of the layer stack is removed between adjacent pixels to be formed from the n-doped side and from the p-doped side up to or into undoped cladding layers or up to just before or to the active region. The removal may be performed by means of an etching process.

However, after removal, a material junction remains between the adjacent pixels comprising the active region and optionally a small region above, below or from both sides. This comprises a maximum thickness dC at which electrical and/or optical conductivity is effectively reduced by the material junction.

With the proposed concept, on the one hand, an array of pixels can be generated over a wide area. The etching process removes material, but a material junction remains between adjacent pixels or subpixels, which comprises the active layer. Thus, the etching process just does not increase the defect density in the region of the active layer, especially in the pixel regions. Nevertheless, the individual pixels or subpixels are optically and electrically separated from each other. Thus, it is proposed to perform a fabrication of pixel emitter arrays without etching through the active region in such a way that optical and electrical crosstalk as well as performance and reliability degradation of etched active regions are avoided. In this way, etch defects are avoided or their number is effectively reduced.

In this context, a pixel or subpixel comprises at least one optoelectronic component or LED that emits light during operation. As a rule, several subpixels of different colors are combined to form a pixel, also referred to as a picture element.

According to one embodiment, the removed material may be at least partially replaced by means of a filler material. In other words, after partial removal of the material and in particular the n-doped or p-doped layers, the resulting space is refilled to provide a planar surface. Thus, the functions of mechanical support, bonding and/or electrical insulation can be provided.

According to a further embodiment, the removed material may be at least partially replaced by a material having a relatively small band gap and thus absorbing light of the active region. This effectively reduces optical crosstalk. Alternatively, the removed material may be at least partially replaced with a material having a large refractive index, particularly greater than the refractive index of one of the cladding layers or the active region. This can effectively create highly refractive interfaces that stop fundamental modes from propagating. Further alternatively, in one aspect, light absorbing material and/or material having a large refractive index may be applied to a respective material junction. In this way, the material affects a waveguide in the material junction and thus prevents crosstalk.

According to a further embodiment, the material with a large refractive index can be formed by diffusing or implanting a material increasing the refractive index into a filling material, in particular up to a respective cladding layer. Thus, the arrays can be effectively improved with respect to crosstalk in a simple manner without etching.

Another aspect relates to a reduction of electrical crosstalk. Accordingly, a material for increasing light absorption and/or a material for increasing electrical resistance may be introduced into the active region of a respective material junction. The respective methods are relatively simple to perform. Thus, the arrays can be effectively improved with respect to crosstalk in a simple manner without etching.

According to a further embodiment, at least one optical structure, in particular a photonic crystal and/or a Bragg mirror, may be generated along, at or in the material junctions. These are particularly effective elements for reducing optical crosstalk. Such a photonic crystal or structure may also be used to improve collimation of light.

In another aspect, an electrical bias may be applied to the two major surfaces of the material junctions by means of two opposing electrical contacts and an electric field may be generated by a respective material junction. This is an effective element for reducing optical crosstalk. In this case, the electric field is generated by applying a bias voltage. This bias voltage may, for example, be derived from or originate from the voltage used to drive the pixels. However, in some aspects, such a field may also be determined by an inherent material property. For example, in one aspect, it is provided that an electric field is generated by a respective material junction by means of an n-doped material and/or p-doped material applied or grown on at least one of the two main surfaces of the material junctions. Electric fields are thus incorporated into the respective array, whereby application of a voltage is not required.

According to a further embodiment, the exposed main surfaces of the material junctions and/or exposed surface regions of the pixels may be electrically insulated and passivated by means of a respective passivation layer comprising, in particular, silicon dioxide. In this way, current flow through selected regions of an array, in particular through the material junction acting as a waveguide, can be effectively and specifically prevented. The main surfaces of the pixels may be electrically contacted by means of contact layers, thereby creating a vertical optical device. One of the main surfaces may thereby be electrically conductively connected to each other via a shared layer. According to a further embodiment, the material and/or the material junctions between a pixel and its adjacent pixels can be formed differently from one another, in particular depending on the direction.

OLEDs, among others, have been proposed for displays with active pixel-sized light sources. A disadvantage is their insufficient luminance and limited service life. An alternative for self-luminous light sources, which promises a long lifetime and high efficiency as well as a fast response time, is the use of LEDs arranged in matrix form, for example based on GaN or InGaN. These are particularly suitable for display arrangements with a high packing density for the formation of a high-resolution display.

The starting point of the consideration is a Display device comprising an IC substrate component and a monolithic pixelated optochip mounted thereon. As used herein, a monolithic pixelated optochip is understood to be a matrix-shaped array of light-emitting optoelectronic components formed on a coherent chip substrate by a common manufacturing process. The IC substrate device has monolithic integrated circuits, which in turn result from a common fabrication process. Furthermore, IC substrate contacts arranged as a matrix are present on an upper surface of the IC substrate component facing the monolithic pixelated optochip.

The monolithic pixelated optochip comprises a semiconductor layer stack with a first semiconductor layer having a first doping and a second semiconductor layer having a second doping, the polarity of the charge carriers in the first semiconductor layer differing from that of the second semiconductor layer. Preferably, the first semiconductor layer and the second semiconductor layer extend laterally throughout the monolithic pixelated optochip. For one embodiment, the first semiconductor layer may have p-doping and the second semiconductor layer may have n-doping. Reverse doping is also possible, as is the use of multiple sub-layers of the same doping for at least one of the semiconductor layers that differ in doping strength and/or with respect to the semiconductor material. In particular, the semiconductor layer stack may form a double heterostructure. Between the first semiconductor layer and the second semiconductor layer, there is a region with a junction in which light-emitting active regions are formed during operation of the display. For one possible embodiment, the active region is located in a doped or undoped active layer disposed between the first semiconductor layer and the second semiconductor layer and having, for example, one or more quantum well structures.

The individual light-emitting optoelectronic light sources of the pixelated optochip each represent LEDs arranged as a matrix, each LED having an LED back surface facing the IC substrate device and a first light source contact contactingly adjacent to the first semiconductor layer and electrically conductively connected to a respective one of the IC substrate contacts. In other words, each LED in the pixelated optochip is formed to include a region of one of the aforementioned active layers. Between adjacent LEDs, the active layer or another of the aforementioned layers may be interrupted so that crosstalk is avoided.

The inventors have realized that a display arrangement simplified in terms of manufacturing technology with a high packing density can be realized if the projection area of the first light source contact on the LED rear side is at most half the area of the LED rear side, and the first light source contact is surrounded by a rear-side absorber in the lateral direction. As used herein, the lateral direction is understood to be a direction perpendicular to a stacking direction determined by averaging the surface normals of the semiconductor layer stack.

A first light source contact applied over a small area, which is significantly smaller than the pixel area of the associated LED, results in a lateral narrowing of the current path in the semiconductor layer stack. Consequently, the lateral extent of an active region is limited to [μm] dimensions, so that individually drivable LEDs are delimited from each other due to the localized recombination zone within the semiconductor layer stack. More conveniently, the pixel size of each LED, defined herein as the maximum diagonal area of the LED backside, is chosen to be <1500 μm and preferably <900 μm and in particular in the range of 200 μm to 1200 μm. Still smaller is the preferred first light source contact, wherein for advantageous embodiments the projection area of the first light source contact onto the LED rear side occupies at most 25% and preferably at most 10% of the area of the LED rear side.

In order to limit the lateral expansion of the active region, preferably the first semiconductor layer and the second semiconductor layer are formed with a p-type or n-type conductivity smaller than 10⁴ Sm⁻¹, preferably smaller than 3*10³ Sm⁻¹, more preferably smaller than 10³ Sm⁻¹, so that the lateral expansion of the current path is limited. In addition, it is advantageous if the layer thickness of the first semiconductor layer in the stacking direction is at most ten times and preferably at most five times the maximum diagonal of the first light source contact in the lateral direction.

For a further embodiment, a first light source contact on the monolithic pixelated optochip is not directly adjacent to the associated IC substrate contact. Instead, with respect to the stacking direction, below the first light source contact is the actual optochip contact element whose cross-sectional area is larger than that of the first light source contact. This measure simplifies the positioning of the monolithic pixelated optochip on the IC substrate component and the mutual contacting without deteriorating the lateral limitation of the current path.

According to the invention, the area around the small-sized first light source contact is used to arrange a rear absorber which reduces the optical crosstalk between adjacent LEDs. In particular, the downwardly directed electromagnetic radiation emanating from the active region in the angular position is absorbed insofar as a limiting angle to the stacking direction is exceeded. Preferred materials for the rear absorber are structured layers with silicon, germanium and gallium arsenide. It is also possible to incorporate graphene or carbon black particles in the rear absorber.

The rear absorber laterally surrounds and extends laterally from the first light source contact, wherein rear absorbers of adjacent LEDs are adjacent to each other and are preferably integrally formed. For one embodiment, the backside absorber extends in the stacking direction at least to the first semiconductor layer. For a further embodiment, a partial section of the back-side absorber extends within the correspondingly structured first semiconductor layer and shields the boundary region between adjacent LEDs. For this purpose, reflectively acting radiation blockers, such as structured elements of reflector materials, such as aluminum, gold or silver, or of dielectric materials whose refractive index is smaller than that of the first semiconductor layer, may additionally or alternatively be used. For a further design, the backside absorber not only fulfills an optical function, but this also serves as an electrical insulator for lateral limitation of the current path.

The display arrangement comprises, in the stacking direction above the second semiconductor layer for each LED, a second light source contact which is made of a transparent material, such as indium tin oxide (ITO), and is electrically conductively connected to a transparent, extensive-area contact layer on the front side of the pixelated optochip. For an advantageous embodiment, the second light source contact is formed by the large-area contact layer itself, so that the entirety of the second light source contacts of the LEDs arranged in matrix form can be applied as a common area contact. For an alternative embodiment further reducing optical crosstalk, the second light source contact adjoins each contacting contact layer, wherein second light source contacts of adjacently arranged LEDs are separated from each other by a front-side absorber in a lateral direction perpendicular to the stacking direction. The frontside absorber may comprise a material absorbing electromagnetic radiation emitted from the active region or a material reflecting such radiation. Additionally or alternatively, the frontside absorber may act as an electrical insulator and contribute to the lateral restriction of the current path for localizing the recombination zone to a region of [μm] dimension.

For a possible further embodiment, the front side absorber extends opposite to the stacking direction at least in a part of the second semiconductor layer. Furthermore, the lower and/or the upper sides of the second light source contact and/or the contact layer and/or the upper side of the second semiconductor layer may comprise an optically effective structuring for improving the light decoupling.

For a proposed method of manufacturing a display device, an IC substrate component with monolithic integrated circuits and with IC substrate contacts arranged as a matrix is electrically conductively connected to a monolithic pixelated optochip. For the preceding fabrication of the monolithic pixelated optochip, a semiconductor layer stack with a first semiconductor layer having a first doping and a second semiconductor layer having a second doping is preferably epitaxially grown, wherein the polarity of the charge carriers in the first semiconductor layer differs from that of the second semiconductor layer and the semiconductor layer stack defines a stacking direction. Furthermore, LEDs arranged as a matrix are laid out in the pixelated optochip, each LED having a rear side facing the IC substrate component and a first light source contact which is contactingly adjacent to the first semiconductor layer and is electrically conductively connected to a respective one of the IC substrate contacts. According to the invention, the first light source contact is formed with such a size that its projection area with a surface normal perpendicular to the stacking direction occupies at most half of the area of the rear surface of the LED. In addition, the first light source contact is surrounded by a rear absorber in a lateral direction perpendicular to the stacking direction.

### DESCRIPTION OF THE FIGURES

Hereinafter, the invention will be explained in more detail with reference to the drawings.

FIG. 1 shows an illustration of an embodiment of an optoelectronic component comprising an LED semiconductor element and a dielectric filter according to some aspects of the proposed principle;

FIGS. 2A and 2B are illustrations of an embodiment of an optoelectronic component comprising an array of a plurality of semiconductor elements; and

FIGS. 3A to 3E are illustrations of two further embodiments of a multiple LED optoelectronic component according to some aspects;

FIG. 4 shows a simplified structure of a display with pixel elements arranged in rows and columns;

FIG. 5 shows an enlarged section of a display according to the previous figure with a pixel element and sub-pixels;

FIG. 6 shows a schematic vertical sectional view through a section of a display according to the proposed concept with a pixel element separation layer and sub-pixel separation elements;

FIG. 7 shows steps of a method for calibrating a pixel element with a pixel element separation layer and sub-pixel separation elements;

FIG. 8 shows a first embodiment of a pixel array according to some aspects of the proposed principle, in which adjacent pixels are connected by a thin bridge of material;

FIG. 9 shows a second example of a pixel array with two LEDs connected by a material bridge;

FIG. 10A is a third embodiment of a pixel array having some aspects according to the proposed principle;

FIG. 10B is a diagram of the embodiment of the previous figure, illustrating the energy curve as seen from the material bridge;

FIG. 11 shows a fourth embodiment of a pixel array having some aspects according to the proposed principle;

FIG. 12A is a fifth embodiment of a pixel array;

FIG. 12B illustrates an embodiment of a pixel array having adjacent LEDs, a material bridge, in which an outcoupling structure is also provided in accordance with some of the aspects disclosed herein.

FIG. 13 illustrates a sixth embodiment of a pixel array;

FIG. 14 is a seventh embodiment of a pixel array with further aspects;

FIG. 15 illustrates an eighth embodiment of a pixel array;

FIG. 16 shows a ninth embodiment of a pixel array;

FIG. 17 shows an embodiment example with various steps for a method of manufacturing a pixel array according to the proposed concept;

FIG. 18 shows an embodiment of a display device comprising a monolithic pixel array with a monolithic IC in cross-sectional view according to some aspects of the proposed concept;

FIG. 19 shows the previous embodiment of the proposed display device in cross-sectional view with a sketched possible light path;

FIG. 20 illustrates a second embodiment of the proposed display device with monolithic pixel array and IC in cross-sectional view;

FIG. 21 shows a fourth embodiment of the proposed display device in cross-sectional view with additional measures for light guidance;

### DETAILED DESCRIPTION

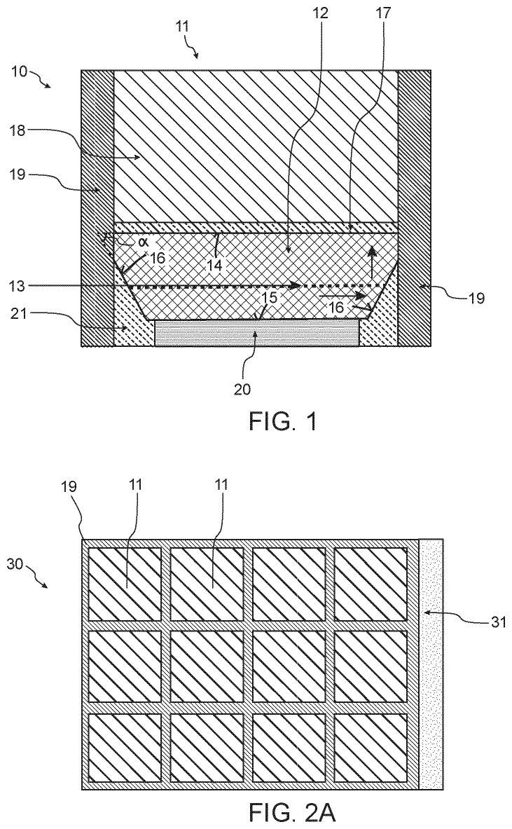

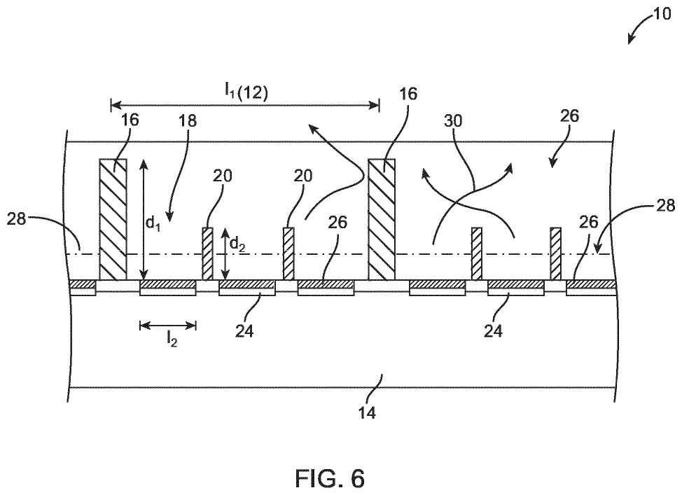

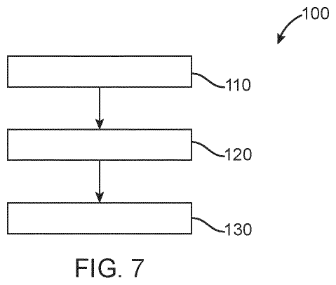

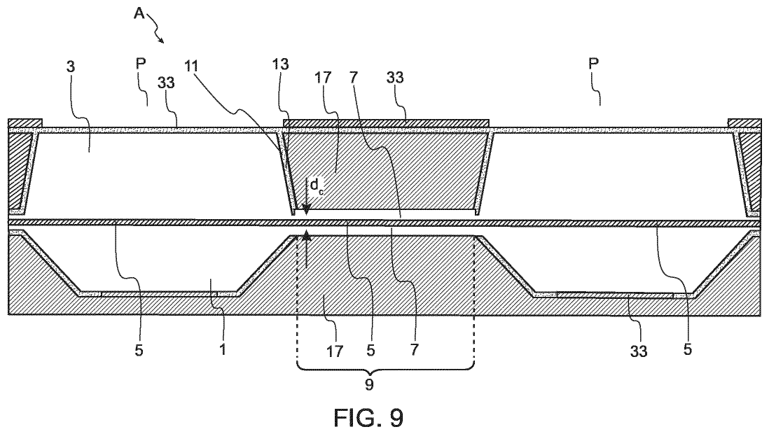

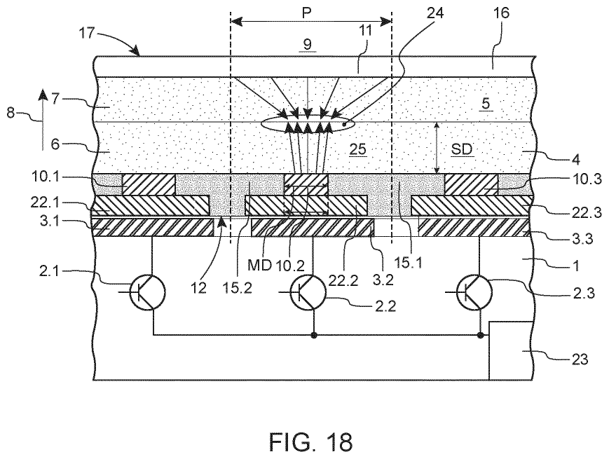

The following embodiments relate primarily to display devices and displays thus to base units and modules having monolithically integrated optoelectronic components. However, the present invention is not limited to this application or to the monolithic devices illustrated. Rather, the principles and embodiments presented can be generalized to be suitable for a wide variety of electronic applications and uses where scaling is necessary. In particular, the aspects for directional radiation can be combined with the aspects for pixel redundancy and the aspects from FIG. 18. The same applies to the embodiments of FIGS. 18 to 21, the principles of which are suitable for combination with, for example, the embodiments of FIGS. 5 and 6 or also FIGS. 8 to 16. The examples shown here can be combined with a mirror as shown in FIG. 1 or also 2B. This does not only concern the embodiments, but extends in particular also to the features of these aspects, which are set forth in the patent claims.

For monolithic displays, where the individual optoelectronic components are spaced by a defined distance, a defined radiation pattern is required for some applications. Other applications requiring a Lambertian radiator can be easily modified based on a solution for directional radiation by applying an additional diffuser element. Therefore, a solution with an improved and directional radiation characteristic of a LED to which a dielectric filter with additional reflecting sides is applied The new monolithic display is a suitable starting point for a wide range of applications.

FIG. 1 schematically shows an optoelectronic component 10 in cross-section. In the following, the structure, the mode of operation and the manufacture of the optoelectronic component 10 are described.

The optoelectronic component 10 includes a pixel 11 having an optoelectronic component in the form of an LED also referred to as an LED semiconductor element 12. The LED semiconductor element 12 includes an active region 13 configured to generate light, and has a height in the range of 1 to 2 μm. The LED semiconductor element 12 comprises a first main surface 14, a second main surface 15 opposite the first main surface 14, and, for example, four side surfaces 16. The side surfaces 16 are each bevelled in the lower region in such a way that they form an angle a with the first main surface 14 of less than 90° in the bevelled region. The active region 13 is located at the level of the bevelled area.

The first major surface 14 of the LED semiconductor element 12 includes a layer 17 that includes a random or deterministic topology. Alternatively, a corresponding topology may be etched into the first major surface 14 of the LED semiconductor element 12.

Deposited over the layer 17 is another layer, not shown in FIG. 1, which comprises a different refractive index than the layer 17. The layer 17, in combination with the layer deposited above it, causes light that does not emerge from the LED semiconductor element 12 perpendicular to the first main surface 14 to be redirected in other directions, for example by reflection at the interface between the layer 17 and the layer disposed above it. Additionally, the layer disposed above the layer 17 has the function of providing a smooth surface on which dielectric mirror layers can be deposited.

Above the layer 17, as well as the layer with the smooth upper surface above it, there is a dielectric filter 18 which comprises a stack of dielectric layers and is configured in such a way that it only transmits light components within a predetermined angular cone, while flatter beams are reflected. The angular cone is oriented with its axis perpendicular to the first major surface 14 of the LED semiconductor element 12.

Further, a reflective material 19 is deposited on all side surfaces 16 of the LED semiconductor element 12, the reflective material 19 being electrically conductive and for example made of a metal. The reflective material 19 is in contact with the n-doped region of the LED semiconductor element 12. Below the second main surface 15 of the LED semiconductor element 12 there is a reflective layer 20 which is also electrically conductive. The reflective layer 20 is in contact with the p-doped region of the LED semiconductor element 12.

The beveled side surfaces 16 of the LED semiconductor element 12 are covered by an electrically insulating first material 21. The electrically insulating first material 21 is disposed between the material 19 and the layer 20, and provides electrical insulation between the n and p contacts of the LED semiconductor element 12. Further, the material 21 comprises a low refractive index to reflect light exiting the LED semiconductor element 12 at the beveled side surfaces 16.

The layer formed of the reflective material 19 is such that it completely surrounds the pixel 11 in the horizontal direction and extends over the entire pixel 11 in the vertical direction. That is, the layer of reflective material 19 extends from the bottom of the electrically insulating first material 21 through the LED semiconductor element 12 to the top of the dielectric filter 18. Any light emerging laterally from the pixel 11 is reflected back by the reflective material 19, so that light with high directionality can only emerge from the top of the optoelectronic component 10.

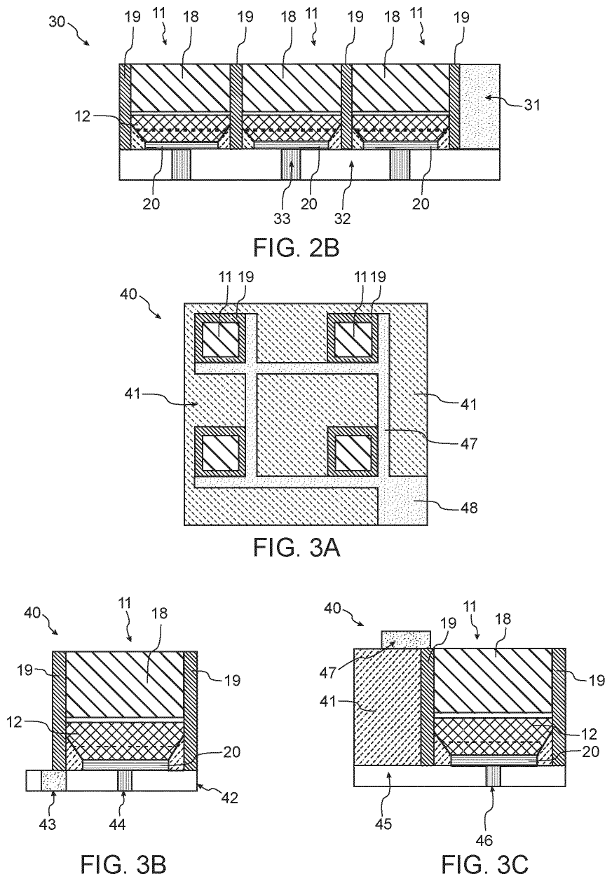

FIGS. 2A and 2B schematically show an optoelectronic component 30 in a plan view from above and in cross-section, respectively. The optoelectronic component 30 includes a plurality of pixels 11 as described above. The pixels 11 are arranged in an array and are separated from each other by reflective material 19, which extends through the optoelectronic component 30 in a grid pattern. An external connector 31 is provided on one side of the optoelectronic component 30, which allows the n-regions of the LED semiconductor elements 12 to be contacted from outside the optoelectronic component 30. In the present embodiment, the anodes of the LED semiconductor elements 12 are connected to each other, which is referred to as a common-cathode arrangement. A common-cathode arrangement, in which the cathodes are connected to each other, is also possible.

The array of pixels 11 is placed on a carrier 32. The carrier 32 has a p-contact terminal 33 for each p-contact, so that the p-contacts of each of the pixels 11 can be individually driven, for example by an IC. The optoelectronic component 30 allows a very high pixel density. In addition, the monolithic structure allows the arrangement to be scaled to a large extent.

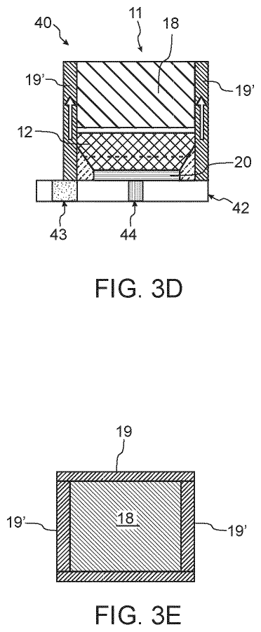

FIGS. 3A, 3B and 3C show an optoelectronic component 40 in a top view and in cross-section, respectively, with two different variants shown in FIGS. 3B and 3C.

The optoelectronic component 40 includes a plurality of pixels 11, the pixels 11 not being arranged directly adjacent to each other as in the optoelectronic component 30 shown in FIGS. 2A and 2B, but being spaced apart. Each pixel 11 is completely covered by the reflective material 19 on its four side surfaces in the optoelectronic component 40. The space between the pixels 11 is filled with an electrically insulating second material 41, for example a potting material.

The n-contacts of the LEDs in the pixels 11 may be connected to the bottom side or to the top side or between the top and bottom sides of the optoelectronic component 40. In FIG. 3B, the pixels 11 are placed on a carrier 42 which integrates n-contact terminals 43 connecting the n-contacts of the pixels 11. Further, the carrier 42 includes a p-contact terminal 44 for each p-contact so that the p-contacts of each pixel 11 can be individually driven. The carrier 42 may further include an IC. The spaced apart arrangement of the LED semiconductor elements 12 in the optoelectronic component 40 further allows for contacting in which both the n-contact and the p-contact of each pixel 11 are individually drivable.

FIG. 3C shows an alternative variant in which a carrier 45 contains only individual p-contact terminals 46 for each pixel 11 disposed on the carrier 45. Of course, P-doped and n-doped layers may be interchanged. On the electrically insulating second material 41, conductive tracks 47 are arranged in a lattice which interconnect the n-contacts of the pixels 11 and lead to an external connector 48 arranged on one side of the optoelectronic component 40, as FIG. 3A shows.

FIG. 3D shows an embodiment in which a dielectric layer 19′ is formed on two opposite sides of a substantially rectangular semiconductor element or LED 12. In plan view in FIG. 3E, it can be seen that the dielectric elements 19 and 19′ alternately wrap around the semiconductor element 12 and the dielectric filter 18. Dielectric elements 19 and 19′ are configured differently. Element 19′ comprises at least one electrically conductive portion, for example in the form of a surface along the sidewall of the LED 12 or even in the form of a plurality of strips extending along the sidewall. Element 19 is not electrically connected to LED 12, thus does not contribute to the power supply of element 12.

The direction of current is indicated by the arrow in FIG. 3D. The current flows either to the surface and from there through the dielectric filter 18 into the semiconductor layer to the active area. Alternatively, the conductive portion of the dielectric element is in contact with a contact layer on the LED. For example, the contact layer could be disposed between the dielectric filter and the LED and could be configured as a top electrode, such as that shown in FIG. 3A by the thin undesignated layer between the elements 12 and 18. In both cases, the contact layer serves to expand the current over the entire surface.

The following remarks concern various aspects of Processing which can be used for the semiconductor structures in order to improve their properties or to create new fields of application or realization possibilities.

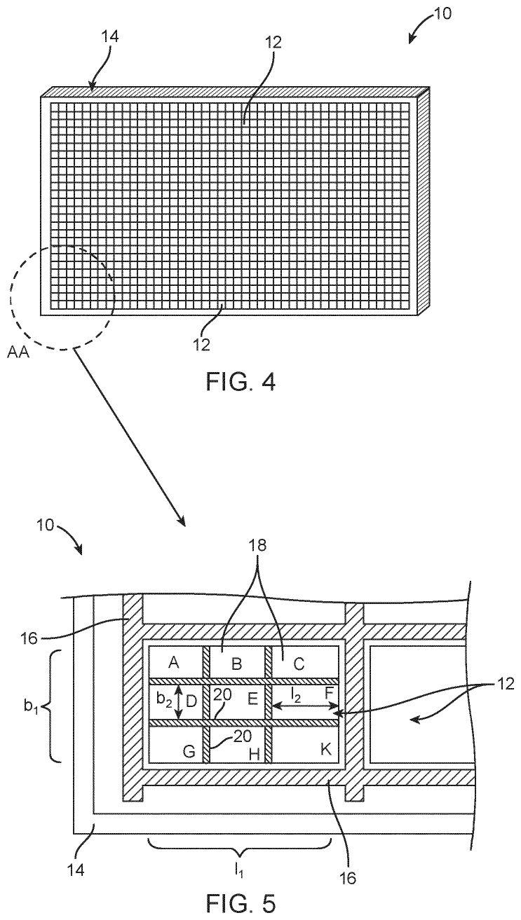

FIG. 4 shows the derivation of the aspect of Pixel elements with electrically separated and optically coupled subpixels a simplified schematic representation of an electronic display 10 is shown, such as is frequently used in, for example, monitors, televisions, display panels or also small devices such as smart watches or smartphones. In this regard, the basic structure is known to be implemented via a close adjacent arrangement of a plurality of pixels or pixel elements 12 in a plane. The pixel elements 12 are organized in rows and columns and can be individually controlled electronically. The control is such that they are varied in this manner both in their luminosity and in their hue and emitted wavelength. In the latter case, each pixel often comprises three sub-pixels which are themselves configured to emit different wavelengths. The pixel elements 12 are often deposited on a substrate or a support structure 14, which in this aspect are mainly intended to ensure mechanical stability of the arrangement.

In this embodiment, it is readily apparent that in order to generate a sufficiently high resolution, in some cases several million such pixel elements 12 must be spatially densely arranged both mechanically and electrically connected. At the same time, in many cases defective pixels 12 may be visible as dark spots between the active pixels. Particularly due to extremely small dimensions, for example for LEDs, the density and resolution of such displays increases on the one hand, and on the other hand there is at the same time a need for as fault-free a function as possible and low-reject production.

In FIG. 5, the section AA shown in FIG. 4 is enlarged in order to be able to describe the features of the solution described here in more detail. Thus, substrate 14 is indicated, which at the same time comprises the control elements and serves as a carrier structure for the pixels. Individual pixel elements 12 are provided on the substrate 14, which here are rectangular in shape and have an identical size. These identical sizes of the pixel elements 12 are often advantageous due to the manufacturing process, but according to one example, they can also be of different shapes or sizes. In the example shown here, the pixel element 12 has a length 11 and a width b1. A pixel element separation layer 16 is provided between the pixel elements 12. The latter is in the range of a few μm, for example 2 μm to 100 μm.

The pixel element separation layer 16 is configured such that the adjacent pixel elements 12 are electrically separated with respect to the driving of the respective pixel elements. In FIG. 6, a section of a pixel element is shown in cross-sectional view. The pixel elements 12 are separated by a pixel element separation layer 16 and each comprise sub-pixels 18. The pixel element separation layer 16 provides electrical and optical separation between the pixel elements 12 to prevent light emitted from one pixel element 12 from passing into and being emitted from an adjacent pixel element 12 by optical crosstalk.

Within a pixel element 12, exemplarily for a selected pixel element 12, a further subdivision into subpixels 18 according to the invention is shown here. The subpixels 18, also referred to as so-called fields, have the same size and shape here. Thereby, a length 12 of a subpixel 18 is defined, whereby according to an example, the length 11 of the pixel element 12 can result from a multiple of the length 12 of the subpixels 12 of the same size, together with any gaps. Similarly, a width b2 of a subpixel is indicated, wherein, again according to an example, the width b1 of the pixel element may result from an approximate multiple of the width b2 of the respective subpixels 18 of the same size, including any gaps. In the representation chosen here, the subdivision of the pixel elements 12 into subpixels 18 or so-called fields is shown only for one pixel element 12. However, the structuring is applicable to all pixel elements 12 arranged in a display 10.

A subpixel separation element 20 is also provided between two adjacent subpixels 18 of the same pixel element 12. This subpixel separating element 20 is designed in such a way that an electrical separation takes place with respect to the driving of an associated subpixel (of length 12) (see FIG. 6). The subpixel separation element 20 is further configured to enable optical coupling or optical crosstalk with respect to light emitted from the subpixels 18. In other words, this means that photons or light can cross-talk from one sub-pixel 18 to one or more of the sub-pixels 18 located within the same pixel element 12, but not between two pixel elements 12.

For example, a generation of the various possible emittable colors of a pixel element 12 may be accomplished by a combination of the base colors of red, green, and blue. Consequently, a pixel element 12 may include subpixels 18 capable of emitting different wavelengths of light. In FIG. 5, by way of example, the total of nine subpixels 18 are identified by the letters A through K. According to one example, subpixels A, D and G are red LEDs, subpixels B, E and H are green LEDs and subpixels C, F and K are blue LEDs. If, for example, red light is now to be emitted by the pixel element 12, the subpixels A, D and G are simultaneously controlled via the control electronics. If necessary, the control electronics can be used to test whether all subpixels A, D and G are functioning correctly. This can then be used to set a desired brightness.

If, for example, one of the subpixels A, D or G is defective, the remaining pixels can still be controlled correctly due to the electrical separation. However, due to the optical crosstalk enabled by the subpixel separation element 20, the missing light from the defective subpixel 18 can be compensated by the adjacent subpixels 18. Thus, as long as one subpixel 18 of the same color from a group is functioning and the remaining subpixels 18 of that group are defective, this remaining functioning subpixel 18 could compensate for the malfunctions of the defective subpixels, thereby ensuring a function of the pixel element 12 through redundancy. In one example, optical crosstalk may also occur across multiple subpixels within a pixel element 12. Other possible arrangements would include assigning each of three subpixels 18 to one of the base colors red, green, or blue. Examples of this include the following groupings A/B/C, D/E/F, and G/H/K. However, a diagonal assignment is also conceivable, in which case optical crosstalk should advantageously be possible.

FIG. 6 shows a sectional view through a portion of a display 10. In the lower part of the figure, a substrate 14 is shown, which, among other things, is intended to provide a sufficiently mechanically stable support structure for accommodating the other structural elements. According to one example, this may be a wafer of a silicon IC. The substrate 14 may additionally comprise a driver circuit or drive electronics (not shown) and various electrical connections. These may be implemented, for example, via conductor structures in the integrated circuit. Furthermore, contact structures 24 are provided which may serve to control a subpixel area 26. This is arranged directly adjacent to the contact structures 24 in the example shown here. Via the contact structures 24, it is possible to control an emitter chip 26 individually and selectively via the control electronics.

For example, an epitaxial layer 26 has various layers that allow, among other things, light-emitting diode functionality. For example, a p-n junction may be implemented by correspondingly differently doped layers or may have one or more quantum well structures. Schematically and for simplicity, a region of a p-n junction 28 is indicated here by a dashed line. The structures of the pixel elements 12 and the subpixels 18 are now introduced into the epitaxial layer 26.

In detail, the individual pixel elements 12 are identifiable via pixel element separation layers 16. These each have a length 11, which corresponds to a distance between two pixel element separation layers 16. Within the pixel elements 12, three subpixels 18 are delimitable here in the longitudinal direction. These each have a length 12. Subpixel separation elements 20 are arranged between the individual subpixels 18.

In the example illustrated herein, the pixel element separation layers 16 and the sub-pixel separation element 20 are each formed as a trench or similar structure. This means that the pixel element separation layers 16 and the sub-pixel separation element 20 are each formed as a trench-like, gap-like or similar structure in the epitaxial layer 26, for example by etching. An electrically insulating material, for example SiO2, is then deposited in the trenches. In order to now determine, for example, the electrical and optical properties of these trenches, a trench depth d1 of the pixel element separation layer 16 is selected to be greater than a trench depth d2 of the sub-pixel separation element 20. This may allow optical crosstalk between sub-pixels 18 to be possible due to the smaller depth d2 of the trench of the sub-pixel separation element 20.

In contrast, both optical crosstalk 30 and electrical crosstalk are prevented between two pixel elements 12 by the deeper trench d1 of the pixel element separation layer 16. According to an example, a depth d2 of the trench of the sub-pixel element separation layer 20 is selected to pass through a region of a p-n junction 28. This can advantageously prevent two adjacent subpixels 18 and/or the associated emitter chips 22 from electrically interacting and/or electrical or optical crosstalk from occurring.

In the above example, the pixel element separation layer 16 extends through the active layer to the edge of the opposing radiating surface, but does not cut through it. Thus, the region near the surface may be formed as a common contact connecting all pixels and subpixels to a potential connection. In addition, the pixel element separation layer 16 may include a mirror layer such that a light generated by the pixel is optically redirected. In the example of FIG. 133, the subpixel separation element 20 is also shown to extend through the active layer but terminate shortly thereafter. This eliminates electrical crosstalk, but not optical crosstalk. Depending on the design and manufacturing parameters, the subpixel separation element 20 may also extend only up to the active layer or slightly into it.

While in this embodiment the pixel element separation layer 16 and the sub-pixel separation elements 20 are trenches with substantially vertical sidewalls, the invention is not limited thereto. Deliberate, other shapes may also be chosen which also have further functionality such as light collimation or light guiding. An example of this are sloping side walls for the pixel element separation layer 16.

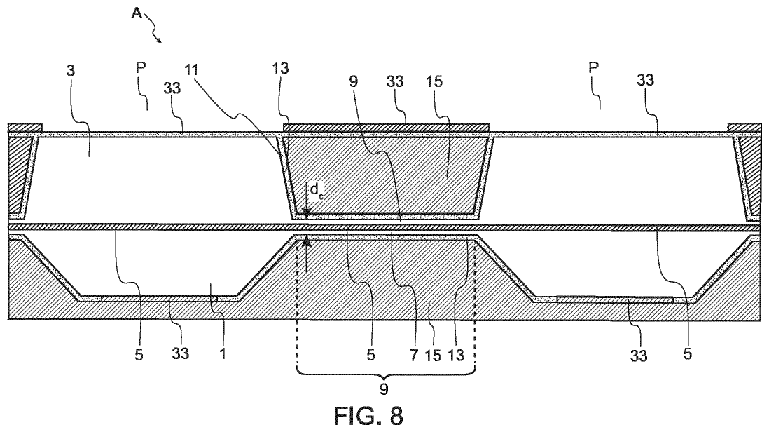

FIG. 7 shows a method 100 according to the invention for calibrating a pixel element 12. Here, in a first step 110, a subpixel 18 of a pixel element 12 is driven as described above and below. This driving of the subpixel 18 is intended to allow a test of the function of the subpixel 18 in question. This can be done, for example, by means of control signals from a control electronics unit, which in turn can be made possible by separately contacting each individual subpixel 18. In a subsequent step 120, a detection of a defect information of a subpixel 18 is performed. In other words, an information is generated here whether the subpixel 18 in question is functioning correctly.

Such defect information may be, for example, a flag or a specific value containing information about a correct function of the sub-pixel 18. This defect information may be stored according to a following step 130, for example, in a memory unit of a driver electronics. This may serve to compensate for defective subpixels by appropriately adapted drive singals of the associated subpixels of the same wavelength, thereby achieving a correct function of the entire pixel element 12.

In one example, the subpixel separating element 20 may be configured to allow optical crosstalk between subpixels 18 of the same color or wavelength, wherein the subpixel separating element 20 is configured to optically separate between subpixels 18 of different colors or wavelengths.

An extension of pixelated or other emitters in which optical and electrical crosstalk between pixels of an array is prevented by a Pixel structure with a material bridge is shown in FIG. 8. It shows a cross-section of an array A in which two adjacent optoelectronic pixels P are connected by a material bridge.

The array A has two optoelectronic pixels P in the form of vertical LEDs which were fabricated over the entire surface. Each pixel P comprises an n-doped layer 1, a p-doped layer 3 and an active region 5 suitable for light emission. Between the two formed pixels P, material of the layer stack has been removed from the n-doped side and from the p-doped side. Only a thin material junction 9 with a maximum thickness dC remains, which comprises the active layer 5 and a thin cladding layer 7. The cladding layer can be formed from the same material as the layers 3 or 5 in terms of manufacturing technology. The material junction is significantly longer than thick. The thickness dC is chosen such that no electromagnetic wave can propagate in the material junction. Optical modes are thus suppressed. In other words, the electrical and/or optical conductivity of the material junction 9 in FIG. 8 is effectively reduced in the horizontal direction.

The two main surfaces of the material junctions 9 exposed as a result of the removal of the material of the layer stack and exposed surface regions 11 of the pixels P are electrically insulated and passivated by means of a respective passivation layer 13 comprising, in particular, silicon dioxide. The areas of removed material of the layer stack are also filled by means of a filler material 15. Finally, the two main surfaces of the pixels P are electrically contacted by means of contact layers 33, which may form end contacts. Contact layers 33 may comprise transparent material, for example ITO, such that the light generated or received by the pixels P passes through the transparent material.

The active region 5 comprises one or more quantum wells or other structures. Their bandgap is tuned to the desired wavelength of the emitted light. The maximum thickness dC is chosen such that all fundamental modes are prevented from propagating along the active region 5 of the material junctions 9 to the next pixel P. The maximum thickness dC of an active region 5 of a material junction 9 for this condition depends on the refractive index difference between the active region 5 and the cladding layers 7 of the material junction 9 corresponding to a waveguide. In general, this means that the material junction should be as thin as possible. On the one hand, this makes crosstalk of optical modes more difficult, since the wave cannot propagate in the horizontal direction. On the other hand, the low maximum thickness dC makes further electrical crosstalk more difficult. The thin cladding layers 7 of the active region 5 surrounding the active region generally exhibit high area resistance and can carry little current. A further reduction also reduces an electrical crosstalk here due to the increasing resistance.

The maximum thickness dC also depends on the refractive index and the thickness of the active region 5. Here, the maximum thickness dC is greater than or equal to the thickness of the active region 5. The maximum thickness dC also depends on the distance between the adjacent pixels P. The greater the distance, the greater the maximum thickness dC can be. A suggested range of the maximum thickness dC is between 100 nm and 4 μm, in particular between 100 nm and 1 μm.

The layers shown in FIG. 8 have thicknesses that depend on the materials used, including the doping materials, the doping profile of concentration versus depth, the angles of the sidewalls, the pixel size, the pixel gaps, and the total array size. A lower limit for the total thickness is about 100 nm.

Suitable material systems for pixels P are, for example, In(Ga,Al)As(Sb,P), SiGe, Zn(Mg,Cd)S(Se,Te), Ga(Al)N, HgCdTe. Suitable materials for contact layers 33 are metals such as, for example, Au, Ag, Ti, Pt, Pd, Cr, Rh, Al, Ni and the like, alone or as alloys with Zn, Ge, Be. Moreover, this material may be used as the filler material 15, which then serves as a bonding material in addition to the filling function. Conductive material also has possible reflective and other properties. Transparent conductive oxides such as ZnO or ITO (InSnO) can also be used as contact layers 33 for bonding and also provide a common contact for either the p-side or the n-side of the array.

Dielectrics such as fluorides, oxides and nitrides of Ti, Ta, Hf, Zr, Nb, Al, Si, Mg can be used as transparent insulators. This material may be used for passivation layers 13. Moreover, this material can be used as the filling material 15, which then serves as an electrical insulator in addition to the filling function. Values of refractive indices of active region 5 and cladding layers 7 depend entirely on the materials used.

The maximum thickness dC also depends on the refractive index of the dielectric produced by means of the passivation layer 13 and/or the filling material 15. The smaller the refractive index difference between the active region 5 and the dielectric, the greater the maximum thickness dC can be for an equal crosstalk.

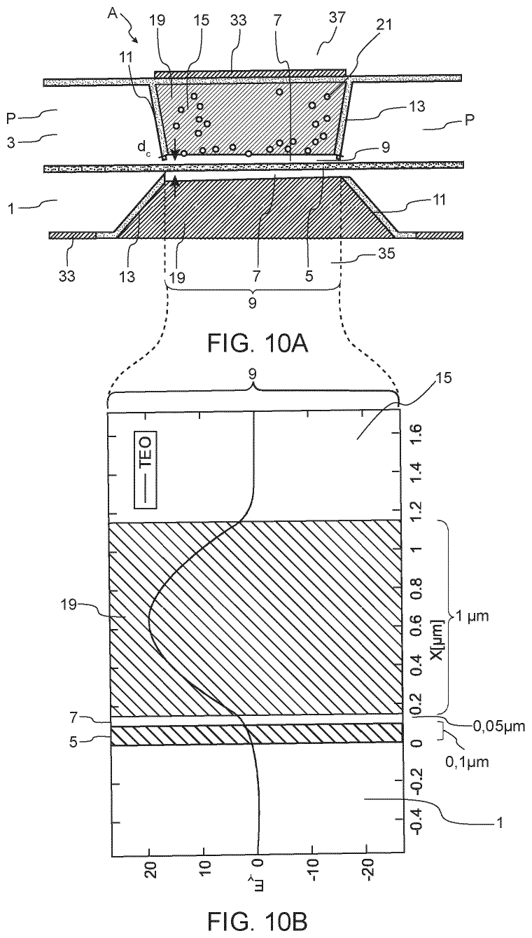

FIG. 9 shows a second embodiment of a pixel array A in cross-section. The array A shown here in FIG. 9 differs from the array A shown in FIG. 8 in that a light absorbing material 17 having a relatively small band gap at least partially fills the regions of the removed material of the layer stack. Further, the light absorbing material 17 is directly adjacent to the material junctions 9 as no passivation layers 13 are formed at these junctions. Only exposed surface regions 11 of the pixels P are electrically insulated and passivated by means of a respective passivation layer 13. Their material may comprise silicon dioxide, for example, so that there is no electrical short circuit between material 3 and 17.

Alternatively, in FIG. 9—not shown there—only one—in FIG. 9 upper or lower—side of the material junction 9 between the two pixels P is filled by the light absorbing material 17. On the other side, for example, a filling material 15 is formed at the material junction 9, leaving the passivation layer 13 between them. By using the light absorbing material 17, additional suppression of optical crosstalk is provided. The light absorbing material 17 between the pixels P reduces waveguiding by absorbing light emerging from the active region 5 in the region of the material junctions 9. Attenuation of waveguiding along the material junctions 9 occurs.

Suitable light absorbing materials 17 include metals, alloys, dielectrics or semiconductors having a smaller band gap than the band gap of the material junction 9 initially acting as a waveguide. Thus, the energy of the light is also greater so that it is absorbed by the material 17. For example, floating eye can be used which absorbs 50% of red wavelengths. The light absorbing material 17 is grown on the material junctions 9, for example, by CVD (chemical vapour deposition) or PVD (physical vapour deposition) by creating epitaxial layers. The light absorbing material 17 has been deposited or grown on the cladding layers 7.

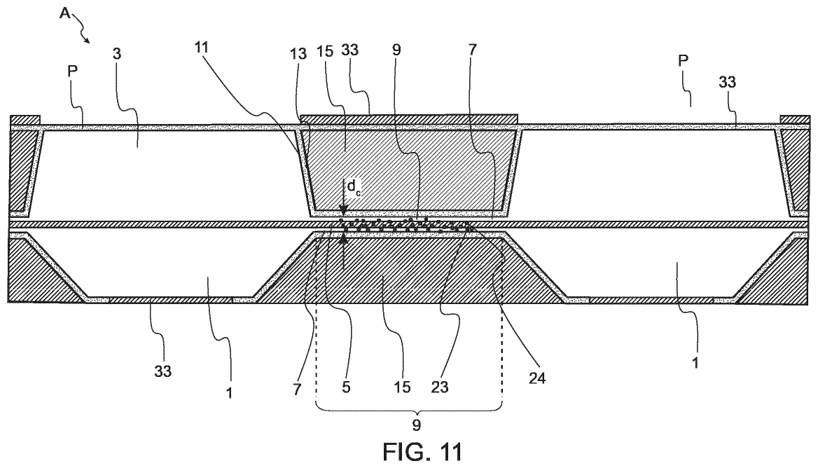

FIG. 10A shows a third embodiment of a pixel array A according to the invention in a cross-section. At the locations of the material of the layer stack of the pixel array removed from the n-doped and/or from the p-doped side, a material 19 is formed with a refractive index which is increased relative to the removed material, in particular relative to the doped material or a filler material 15, but which should not be greater than the refractive index of the cladding layers 7 or the active region 5. This also attenuates waveguiding in the material junction 9. Finally, the layer stack on the substrate 35 is covered by a protective top layer 37.

The material 19 having an increased refractive index is epitaxially grown at the material junctions 9, for example by means of chemical or physical vapor deposition. The application or growth takes place after removal of the original n-doped and/or p-doped layer material between each two pixels P and after passivation of exposed surface regions 11, in particular side surfaces, of the pixels P by means of application of passivation layers 13.

The material 19 having an increased refractive index has been applied or grown here to the cladding layers 7. No passivation layers 13 are formed at the material junctions 9. This represents the region below the material junction 9. For example, GaAs may be grown as material 19 with enlarged refractive index to an active region 5 of a material junction 9 comprising Al-GaAs. Alternatively, the enlarged refractive index material 19 is formed by diffusing or implanting a refractive index increasing material 21 into a filler material 15 up to or into the cladding layers 7. This is represented in FIG. 10A by the region above the material junction 9. The material 19 of increased refractive index may be formed above the material junction 9 and/or below the material junction 9 in FIG. 10A. An area free of greater refractive index material 19 may be filled with a filler material 15.

FIG. 10B shows a simulation of the propagation of light in the material junction region of the third embodiment of a pixel array according to the proposed principle. Shown is a cross-section of a material junction 9 in which only an upper side has been etched and filled with a material 19 having an enlarged refractive index. The material 19 with an enlarged refractive index has a refractive index equivalent to the quantum well material 5, that is, the active region 5 and the material 19 with an enlarged refractive index are shown in dark gray in the diagram. The cladding layer 7 and non-etched semiconductor material of an n-doped layer 1, respectively, and a filler material 15 are shown in white.

The layer only a few 0.1 μm thick in this simulation is the active region 5 or the area of the quantum well material. The 0.05 μm thick layer is still “residual cladding” or a remaining cladding layer 7. The 1 μm thick layer is the material 19 with the increased refractive index. Depending on the distance between the LEDs and the selected material, the individual sections can be larger or smaller.

In the region of the material junction 9 between two pixels P, an active region 5 with a refractive index of 3 and a layer thickness of 0.1 μm is arranged on a lower unetched n-doped layer 1 having a refractive index of 3. A cladding layer 7 with a refractive index of 3 is formed on this first inner layer as a second inner layer of the material junction 9 with a layer thickness of 0.05 μm. A relatively thick third inner layer of a material 19 having an enlarged refractive index of 3.5 and a layer thickness of 1 μm is formed thereon. The third inner layer is covered by a layer comprising a filler material 15 having a refractive index of about 3, for example.

For a simulation on this layer structure, a vacuum light wavelength of 0.63 μm was assumed. The generated light can be TM- and/or TE-polarized here. One speaks of TM-polarized light, if the direction of the magnetic field is perpendicular to the plane spanned by the incidence vector and the surface normal (“plane of incidence”) (TM=transversal magnetic), and of TE-polarized light, if the electric field is perpendicular to the plane of incidence (TE=transversal electric).

For the simulation, FIG. 10B represents with the x-axis the value of a spatial extension x in μm. The y-axis shows the value of a y-component of an electric field strength E. FIG. 10B shows how a fundamental mode TE0 emerges from the active region 5 and is stopped by the further optical barriers present between two pixels P above and/or below the material junction 9 acting as a waveguide. The optical barriers are here the interfaces between the layers of different refractive indices according to the layer structure of FIG. 10A described above. The fundamental mode TE0 enters the thick third inner layer of material 19 with increased refractive index and does not enter the adjacent pixel P.

In practice, a material with a larger refractive index is often also a more absorbent material, in particular due to a smaller band gap.

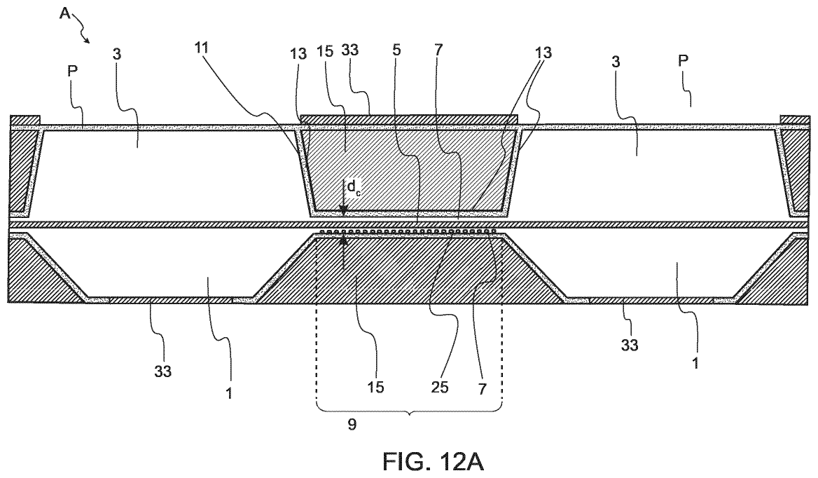

FIG. 11 shows a fourth embodiment of a pixel array A in cross-section. Reference signs which are identical to those in the other figures indicate identical features in FIG. 11. In contrast to a structure according to FIG. 8, additional material 23, 24 is introduced here between two filling layers 15 and two passivation layers 13 into the active region 5 of a material junction 9, which effectively reduces electrical and/or optical conductivities of the material junction 9 acting as a waveguide. The additional material is, on the one hand, a material 23 which increases light absorption in the active region 5 of the material junction 9. An increase in absorption in the active region 5 between pixels P is effected by reducing the band gap of the material of the active region 5. For this purpose, band gap-reducing elements are implanted or diffused into the active region 5 of the material junction 9. In particular, dopants are diffused or implanted into the central region of the active region 5 between pixels P. The reduction of the band gap occurs due to a so-called band gap renormalization. The greater the amount of material 23 introduced along a material junction 9, the greater the absorption of light in the active region 5.

Alternatively or cumulatively, the additional material is, secondly, an electrical resistance increasing material 24 in the active region 5 of the material junction 9. For this purpose, electrical resistance increasing elements are implanted or diffused into the active region 5 of the material junction 9. This further increase in electrical resistance serves to further reduce electrical crosstalk from one pixel P to the adjacent pixel P. For example, Fe may be introduced into an active region 5 of a material junction 9 comprising InGaAsP to increase electrical resistance. The greater the amount of material 24 introduced along a material junction 9, the greater the increase in electrical resistance of the active region 5 of the material junction 9 between two pixels P.

Both materials 23, 24 are diffused or implanted into the active region 5 of a respective material junction 9 prior to an application of passivation layers 13.

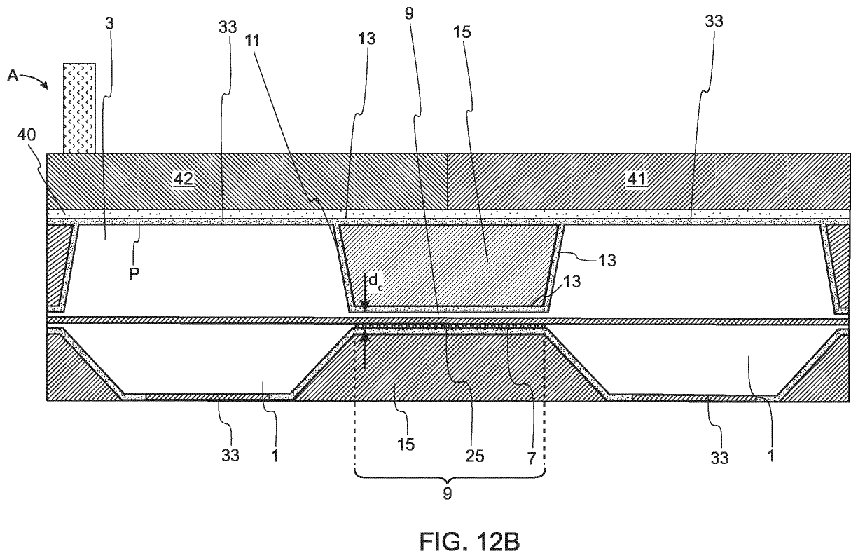

FIG. 12A shows a further embodiment of a pixel array A in a cross-section, in which, in contrast to a structure in FIG. 138, an optical structure 25 is introduced in the region of the material junction. The structure 25 is introduced between two filling layers 15 and two passivation layers 13 along the active region 5 of a material junction 9. This reduces an optical conductivity of the material junction 9 acting as a waveguide between two pixels P. A waveguide is reduced. Optical structures 25 are may be a photonic crystal and a Bragg mirror or another dielectric structure. The structure 25 forms periodic structure of refractive index along the material junction 9 above, below or on both sides of the active region 5, which results in an optical band gap and prevents propagation of photons along the material junction.

The periodicity of the optical structures depends on the wavelengths of light, the size of the optical structures, the length of the structured material junction 9 and the refractive indices of the materials used. In FIG. 12A, only one optical structure 25 is shown at a lower side of the material junction 9 acting as a waveguide. This optical structure 25 may also be formed on the upper side of the material junction 9 acting as a waveguide. The optical structure 25 shown in FIG. 12A is a Bragg mirror. After the optical structures 25 have been formed, passivation layers 13 are applied.

An extension of the example in FIG. 12A is shown in FIG. 12B. A converter material 41 or 42 is applied to the surface. The converter material 41 and 42 each extend to approximately the middle between two LEDs. Since the walls of the LED themselves are reflective, light generated in the active layer of an LED is directed by them towards the converter material. Light entering the converter material from the LED is converted there. An optional reflective layer between the converter materials prevents crosstalk.

Photonic structures 34 and 37 are deposited on the surface of the converter materials on each pixel to direct the light. Alternatively, a dielectric mirror may be provided as described above.

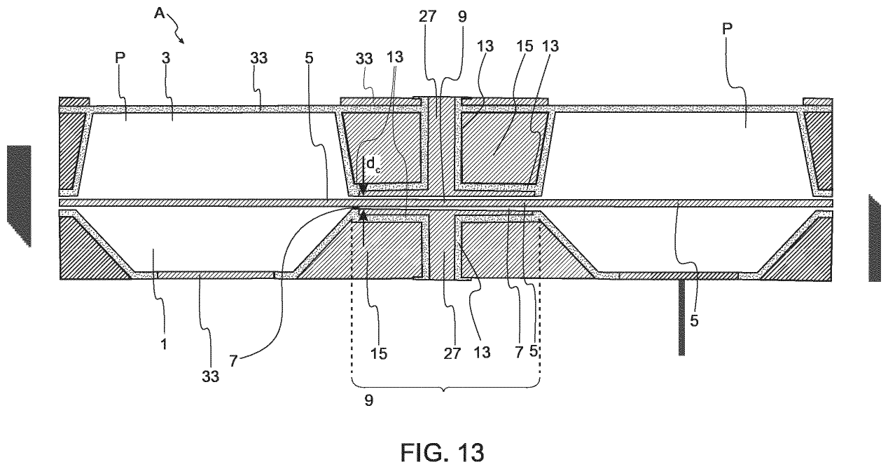

FIG. 13 shows a sixth embodiment of a pixel array A according to the invention in a cross-section. In contrast to a structure according to FIG. 13, here in two filling layers 15, along the active region 5 of a material junction 9, at both main surfaces of the material junction 9 acting as a waveguide, additionally two mutually opposite electrical contacts 27 are introduced, which effectively reduce electrical and/or optical conductivities of the material junction 9 acting as a waveguide between two pixels P. The electrical contacts 27 are arranged on the two main surfaces of the material junction 9 acting as a waveguide. These opposing electrical contacts 27 apply an electrical bias to both main surfaces of a respective material junction 9 between two pixels P.

By means of the applied electrical bias, a static electric field is generated, by means of which the optical properties of the material junction 9, which initially acts as a waveguide, are changed in such a way that waveguiding along the material junction 9 is effectively reduced.

As a result of applying the electric bias voltage to the material junction 9 between the pixels P, which initially acts as a waveguide, an absorption of light in the waveguide is magnified by means of the so-called quantum confined Stark effect (QCSE), as used, for example, in an electroabsorption modulator. In an electroabsorption modulator, a fundamental absorption of a semiconductor is effectively magnified by applying an electric field. Accordingly, an optical crosstalk between pixels P is reduced. Conventional Schottky contacts or metal insulator contacts are suitable as electrical contacts 27. Furthermore, anything conventionally used for tape bending without current flow is suitable.

After forming the two opposing electrical contacts 27, passivation layers 13 are applied to the two opposing electrical contacts 27, in particular to the surfaces thereof where filler material 15 is formed and which are adjacent to the pixels P. Reference signs which are identical to those in the other FIGS. 18 to 12A indicate identical features in FIG. 13.

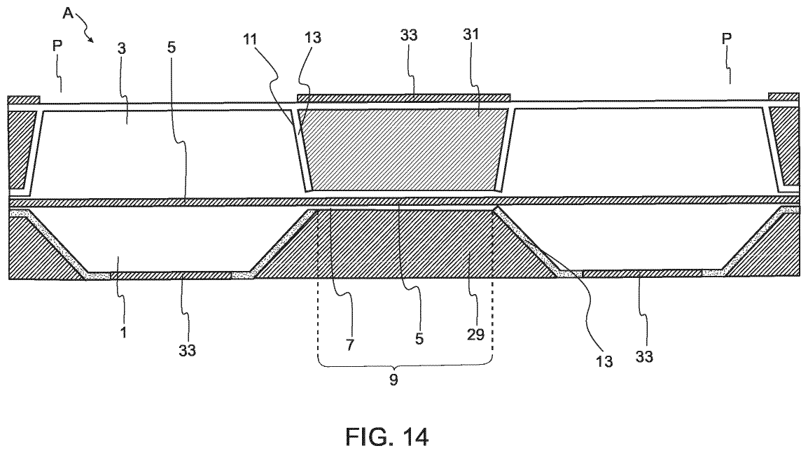

FIG. 14 shows a seventh embodiment of a pixel array A according to the invention in a cross-section. In contrast to the embodiment in FIG. 13, here an electric field is generated inherently, i.e. by the choice of a suitable material system. For this purpose, at least one layer of n-doped material 29 and/or p-doped material 31 is arranged on at least one of the two main surfaces of a material junction 9 in such a way that an electric field is generated by it, which is thus incorporated in the material junction 9 without any further means. When only a layer of doped material is formed on one of the two major surfaces of the material junction 9 and the layer on the other major surface of the material junction 9 is undoped, a so-called depletion field is provided which is sufficient as an electric field for magnifying light absorption in the material junction 9. Alternatively, the electric field for magnifying light absorption in the material junction 9 is provided by forming a layer of n-doped material 29 on one major surface of the material junction 9 and a layer of p-doped material 31 on the opposite major surface of the material junction 9.

The material used to provide the electric field, in particular the n-doped material 29, the p-doped material 31 and, if necessary, the undoped material are epitaxially grown by means of CVD (chemical vapor deposition) or PVD (physical vapor deposition) in such a way that a built-in bias is provided between adjacent pixels P on the thin waveguide. For n- and p-doping, for example, InGaAlP can be doped using Si and Zn.

By means of the doped material 29 and/or 31, a bias is provided which has the same effect as the embodiment according to FIG. 13. Furthermore, the material providing the electric field is directly applied to the material junctions 9, since no passivation layers 13 are necessary at these. Only exposed surface regions 11 of the pixels P are electrically insulated and passivated by means of a respective passivation layer 13. The material thereof may comprise silicon dioxide, for example. The pixels P are electrically connected by means of electrical contact layers 33.

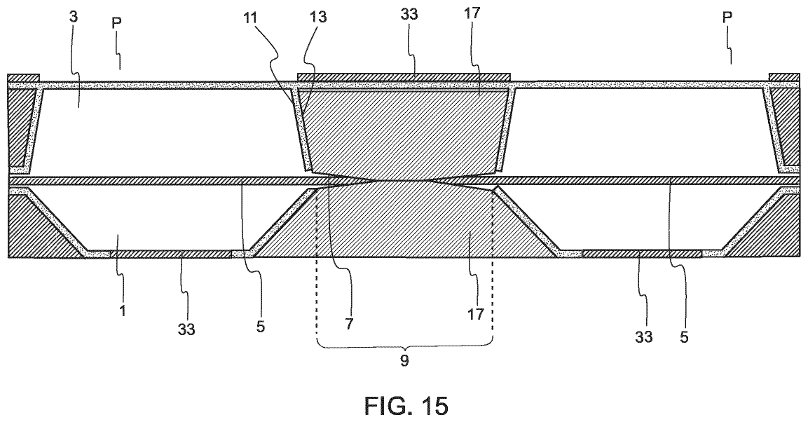

FIG. 15 shows an eighth embodiment of a pixel array A in cross-section. In this, the active region 5 has been etched in a controlled manner. In other words, damage to the active region 5 or the formation of defects in the active region 5 in the region of the material junction is permitted in a controlled manner here. According to FIG. 15, the material junction 9 is completely interrupted at its center to the two pixels P between which the material junction 9 is formed. At the transitions to the two pixels P, the material junction 9 is formed with a maximum thickness dC.

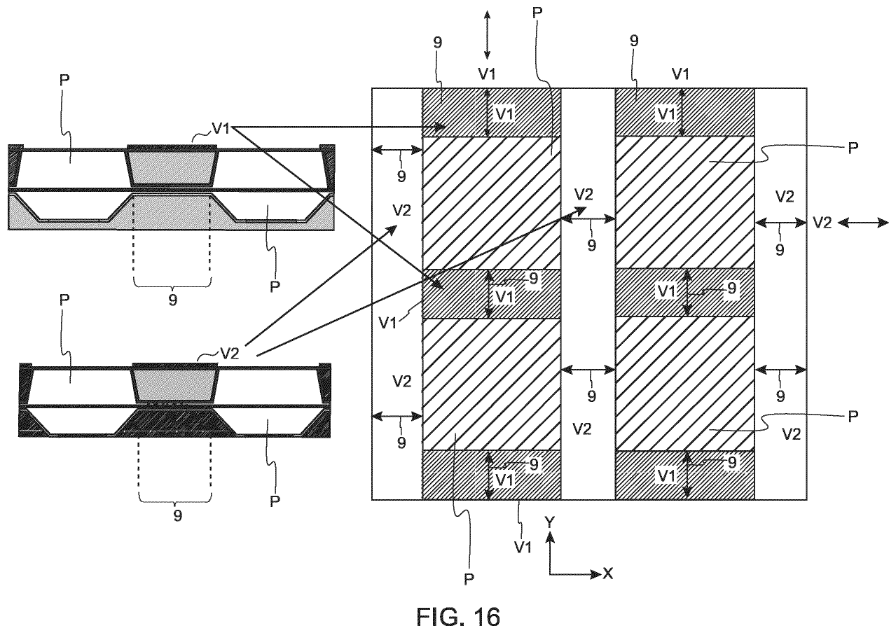

FIG. 16 shows a ninth embodiment of a pixel array A. On the left side, two different embodiments of the suppression of crosstalk between two adjacent pixels P are shown in cross-section. The upper variant V1 shows the first embodiment example according to FIG. 8. The lower variant V2 shows the fourth embodiment example according to FIG. 12A. On the right side, a top view of four mutually adjacent pixels P is shown.

Four adjacent pixels P are assigned to each pixel P, whereby material junctions 9 are formed here along an x-direction in accordance with the second variant V2. Along a y-direction, the material junctions 9 are formed according to the first variant V1. In principle, each material junction 9 can be designed differently from the other material junctions 9, in accordance with the embodiments described in this application. In principle, material junctions 9 may be of the same design along a respective spatial direction. The material junctions 9 may be formed according to desired patterns. Embodiments of material junctions 9 along a respective spatial direction may alternate.

In this way, an array A according to this application comprises all possible embodiments or variants as well as combinations of embodiments of the material junctions 9. It can be seen from the top view in FIG. 16 that all variants V can be combined, for example, depending on the direction. This also applies to all possible shapes of pixels P, which can be round or angular, in particular rectangular in this case.

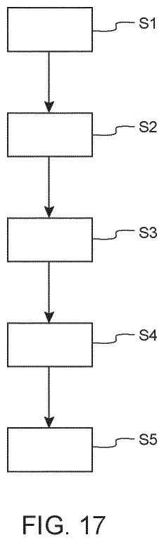

FIG. 17 shows an example of a process according to the invention for producing a pixel array A. The process for producing an array A of optoelectronic pixels P comprises the following steps. With a first step S1, a full-area layer stack of an n-doped layer 1 and a p-doped layer 3 is generated along the array A, between which an active region 5 is formed. Various techniques are carried out and disclosed in this application.

In a second step S2, material of the layer stack is removed from the n-doped side and from the p-doped side between pixels P to be formed, in particular by means of etching. This is done in such a way that at least the active region remains as a material junction. Similarly, thin cladding layers 7 may remain above or below or on both sides of the active region 5 in the material junction 9. The thickness dC is thus significantly reduced and optical modes cannot propagate laterally between the pixels. Likewise, electrical crosstalk is reduced due to the higher resistance. Overall, the electrical and/or optical conductivity of the material junctions 9 is reduced.

The thickness dC is sufficiently thin, which is required according to the specifications for the array A or for a desired device in terms of brightness or response sensitivity. The thickness in the area of the material junction depends, among other things, on the material system and the wavelength of the emitted light.

In one aspect, etching is performed from both sides up to or into the thin cladding layers 7 on each side of the active region 5 or up to the active region 5 such that all fundamental modes are prevented from propagating along the active region 5 to the nearest pixel P. The maximum thickness dC of an active region 5 of a material junction 9 for this condition depends on the refractive index difference between the active region 5 and the cladding layers 7 of the material junction 9 acting as a waveguide.

Reducing the maximum thickness dC results in a reduction of optical crosstalk as more light exits the waveguide. Reducing the thickness dC also means reducing an electrical crosstalk. The thin undoped cladding layers 7 of the active region 5 are and which remain between individual pixels P can hardly carry any current. This therefore reduces electrical crosstalk.

With further steps S3 to S5, after etching, the individual pixels P and the waveguide can be covered with other necessary materials for further suppression of optical and/or electrical crosstalk outside the waveguide. In step S3, the disclosed main surfaces of the material junctions 9 and disclosed surface regions 11 of the pixels P are electrically insulated and passivated by means of a respective passivation layer 13, in particular comprising silicon dioxide. The electrical insulation and passivation of the disclosed main surfaces of the material junctions 9 may be omitted, depending on which measure is applied in the fourth step S4 for reducing crosstalk.

With a fourth step S4, it is carried out from the n-doped side and/or from the p-doped side that at least partially the removed material is replaced, for example by means of a filler material 15. In step S5, contact layers 33 are deposited on the main surfaces of the pixels P, thus electrically contacting the structure. According to one embodiment, steps S1 to S5 are carried out first for one main surface of the array and then, after a substrate change, for the other main surface of the array.

To further reduce optical and/or electrical crosstalk, further measures may be taken in the fourth step S4 cumulative to the formation of the material junctions 9 having the maximum thickness dC. Some are exemplified here, while others are described above with respect to the various embodiments. Thus, from the n-doped side and/or from the p-doped side, regions of the removed material may alternatively be filled with light absorbing material 17 and/or with light more strongly refracting material or material 19 having an increased refractive index, instead of a filler material 15. Here, no passivation layer 13 is formed at the material junctions 9.

Furthermore, in the fourth step S4, the light absorption and/or the electrical resistance of the active region 5 can alternatively or cumulatively be increased. In addition, a passivation layer 13 should then also be applied to the material junctions 9.

Applying these concepts allows the fabrication of arrays A of optoelectronic pixels P, in particular emitter and detector arrays without etching through the active region 5, without optical and electrical crosstalk, and without performance and reliability problems compared to solutions with etched active regions.

Display devices with a high resolution, especially in a monolithic structure, are interesting for a variety of applications. For displays with pixel-sized light sources, so-called displays in matrix form based on GaN or InGaN are proposed.

FIG. 18 shows a display device comprising an IC substrate component and a monolithic pixelated optochip mounted thereon as a first embodiment example in cross-section. Shown is an IC substrate component 1 with monolithic integrated circuits 2.1, 2.2, 2.3 and with IC substrate contacts 3.1, 3.2, 3.3 controlled by these. The IC substrate component 1 may have further components for control, power supply and for signal exchange with peripheral devices, an interface 23 being sketched as an example.

The IC substrate contacts 3.1, 3.2, 3.3. are metallic and each separated by an insulating layer. A monolithic pixelated optochip 4 is arranged on the IC substrate component 1 and is electrically and mechanically connected to the IC substrate contacts 3.1, 3.2, 3.3. More specifically, contacts 22.1, 22.2 and 22.3 are provided on the surface of the pixelated optochip 4 such that they face the IC substrate contacts 3.1, 3.2, 3.3. when accurately positioned on the IC. As shown, the contacts are each of the same size, so that even a small offset as shown has no negative effect and a short circuit is avoided. Various techniques for such a connection are disclosed in this application.

The monolithic pixelated optochip 4 comprises a semiconductor layer stack 5 with a first semiconductor layer 6 with p-doping and a second semiconductor layer 7 with n-doping, the first semiconductor layer 6 and second semiconductor layer 7 being applied over a large area and extending substantially over the entire monolithic pixelated optochip 4 in the lateral direction running perpendicular to the stacking direction 8. Not shown in detail are embodiments of the semiconductor layers 6, 7 having a plurality of individual layers of different doping thicknesses or of different semiconductor materials. Between the first semiconductor layer 6 and the second semiconductor layer 7 there is an active layer with quantum wells, not shown in detail, in the region of which an electromagnetic radiation-emitting active region 24 is formed when current flows through the semiconductor layer stack 5 in the stacking direction 8.

A transparent contact layer 16, for example made of indium tin oxide (ITO), is planarized on the front surface 17 above the semiconductor layer stack 5. To arrive at an LED 9 having a small pixel size P, in the present embodiment example from 200 μm to 1200 μm diagonal size, the first light source contact 10.1, 10.2, 10.3 on the bottom side of the first semiconductor layer 6 facing the IC substrate device 1 is substantially smaller than the pixel size P.

For the embodiment example, a maximum diagonal MD of the first light source contact 10.1, 10.2, 10.3 of 20 μm is selected so that the feature is satisfied according to which the projection area 13 of the first light source contact 10.1, 10.2, 10.3 on the LED back surface 12 is at most half the area of the LED back surface 12. For the present embodiment example, the projection area 13 has a diagonal of 20 μm and is about 5% of the area of the LED rear side 12. This results in a laterally confined current path 25 within the LED 9 between the first light source contact 10.2 and the second light source contact 11 formed by a portion of the transparent contact layer 16, resulting in a laterally confined active region 24. Additionally, non-radiative recombination is suppressed at the edges of the active region 24. To improve the lateral confinement of the current path 25, the dopants of the first semiconductor layer 6 and the second semiconductor layer 7 are preferably selected to have a p or n conductivity smaller than 10⁴ Sm⁻¹, preferably smaller than 3*10³ Sm⁻¹, more preferably smaller than 10³ Sm⁻¹. In addition, it is advantageous to select the layer thickness SD of the first semiconductor layer 6 to be small. It is preferred that the layer thickness SD of the first semiconductor layer 6 in the stacking direction 8 is at most ten times and preferably at most five times the maximum diagonal MD of the first light source contact 10.1, 10.2, 10.3 in the lateral direction.

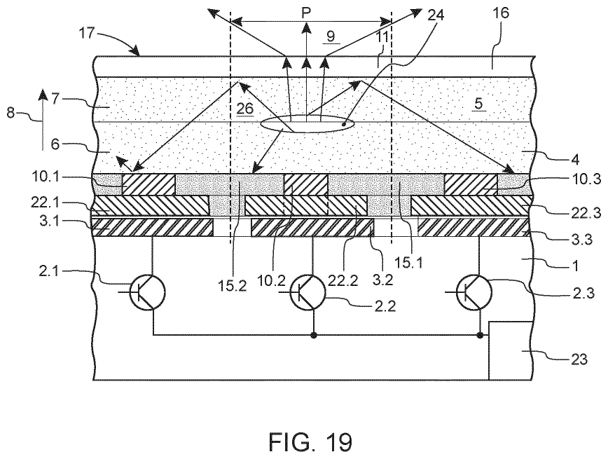

According to the invention, the first light source contact 10.2 is surrounded in a lateral direction perpendicular to the stacking direction 8 by a rear absorber 15.1, 15.2 with an optical blocking effect, the rear absorber 15.1, 15.2 preferably consisting of silicon, germanium or gallium arsenide and/or having a graphene or carbon black particle intercalation. From the light path 26 for the first embodiment shown in FIG. 19, it can be seen that this measure reduces crosstalk from a driven LED 9 into adjacent pixels.

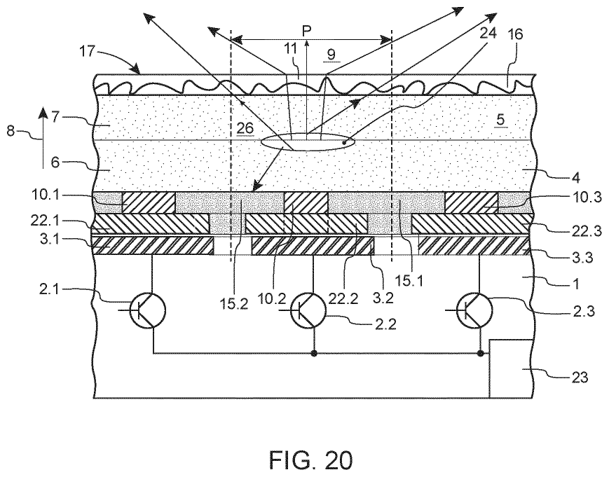

For the second embodiment shown in FIG. 20, the same reference signs are used for the components corresponding to the first embodiment. Shown are three-dimensional structures on the upper surface of the second semiconductor layer 7 which improve the light outcoupling to the front surface 17. It is apparent that the degree of total reflections is reduced and the outcoupling cone is increased. For an alternative embodiment not shown in detail, Fresnel lens structures are provided on the front surface 17. In another alternative, photonic crystal structures are disposed on the surface.

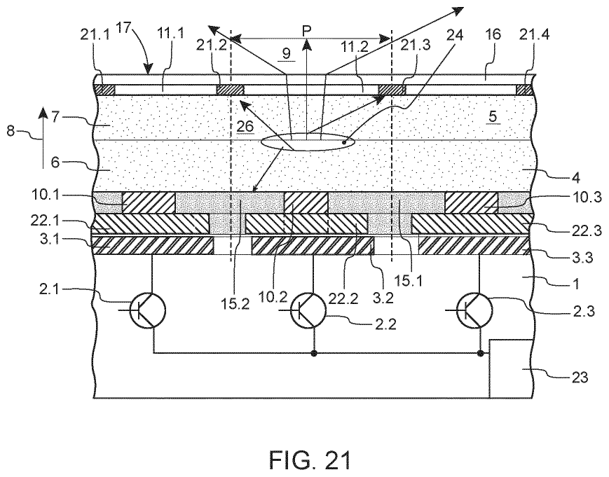

In the fourth embodiment shown in FIG. 21, optical crosstalk between adjacent LEDs 9 is further reduced by a front-side absorber 21.1, 21.2, 21.3, 21.4 laterally surrounding the second light source contacts 11.1, 11.2, 11.3. If the front-side absorber 21.1, 21.2, 21.3, 21.4 is made electrically insulating, the lateral restriction of the current path for the localization of the active region 24 can additionally be improved.

For the embodiments shown in the figures, an optochip contact element 22.1, 22.2, 22.3 is arranged between the first light source contact 10.1, 10.2, 10.3 and the respective associated IC substrate contact 3.1, 3.2, 3.3. The cross-sectional area of the optochip contact element 22.1, 22.2, 22.3 is larger than that of the first light source contact 10.1, 10.2, 10.3, so that the monolithic pixelated optochip 4 can be contacted on the IC substrate component 1 in a simplified manner.

1. An optoelectronic component, comprising:
at least one semiconductor element having an active region adapted to generate light;
a dielectric filter disposed above a first major surface of the at least one semiconductor element and configured to transmit light only in pre-planar directions; and
a reflective material disposed on at least one side surface of said at least one semiconductor element and on at least one side surface of said dielectric filter.

2. The optoelectronic component according to claim 1, wherein at least one side surface of the at least one semiconductor element is sloped at the level of the active region.

3. The optoelectronic component according to claim 1,
wherein the at least one semiconductor element has a first terminal and a second terminal; and
wherein the reflective material is electrically conductive and is coupled to the first terminal of the at least one semiconductor element.

4. The optoelectronic component according to claim 3, wherein the reflective material is made conductive only on two opposite side surfaces of the light source, in such a way that it contacts the first terminal for the power supply.

5. The optoelectronic component according to claim 4, wherein the reflective material on the other two sides is non-conductive, such that it is isolated from the connection to the power supply.

6. The optoelectronic component according to claim 1, wherein the dielectric filter is formed at least partially in a layer of the semiconductor element adjacent to the radiation direction.

7. The optoelectronic component according to claim 1,
wherein the dielectric filter comprises first and second regions having different refractive indices; and
wherein converter material forms the first regions.

8. The optoelectronic component according to claim 1,
wherein said at least one semiconductor element has a second major surface opposite said first major surface; and
wherein a reflective layer is disposed below the second major surface of the at least one semiconductor element.

9. The optoelectronic component according to claim 1, wherein the reflective layer is at least partially electrically conductive and is coupled to the second terminal of the at least one semiconductor element.

10. The optoelectronic component of claim 8, wherein the reflective layer is electrically insulating and one or more electrically conductive layers are disposed above and/or below the reflective layer.

11. The optoelectronic component according to claim 1,
wherein an electrically insulating first material is arranged between the reflective material and the reflective layer; and
wherein the electrically insulating first material in particular comprises a lower refractive index than the at least one semiconductor element.

12. The optoelectronic component according to claim 1, wherein a layer with a roughened surface is arranged between the at least one semiconductor element and the dielectric filter.

13. The optoelectronic component according to claim 1, further comprising:
a converter material on the light emitting surface, the converter material comprising an inorganic dye or quantum dots; or
a converter material between the dielectric filter and the semiconductor material, the converter material comprising an inorganic dye or quantum dots.

14. The optoelectronic component according to claim 1, wherein the first major surface of the at least one semiconductor element comprises a roughened surface.

15. The optoelectronic component according to claim 1, wherein the at least one semiconductor element has a lateral extent of at least 140 μm and/or a height of at least 5 μm.

16. The optoelectronic component according to claim 1, wherein the at least one semiconductor element comprises a plurality of semiconductor elements arranged in an array, adjacent semiconductor elements being separated from each other by the reflective material.

17. The optoelectronic component of claim 11, wherein the reflective material is electrically conductive and the first terminals of the semiconductor elements are connected to a common external terminal via the reflective material.

18. The optoelectronic component according to claim 1,
wherein the at least one semiconductor element comprises a plurality of semiconductor elements arranged side by side; and
wherein an electrically insulating second material is arranged between adjacent semiconductor elements.

19. The optoelectronic component according to claim 1, wherein the reflective material is electrically conductive and conductive tracks extend above and/or below and/or within the electrically insulating second material connecting the first terminals of the semiconductor elements to a common external terminal.

20. The optoelectronic component according to claim 1, wherein the second terminals of the semiconductor elements are individually drivable.

21. The optoelectronic component according to claim 1, further comprising a lens disposed above the dielectric filter.

22. A method of manufacturing an optoelectronic component comprising:
providing at least one semiconductor element, having an active region configured to generate light;
arranging a dielectric filter above a first major surface of said at least one semiconductor element, said dielectric filter being configured to transmit light only in pre-planar directions; and
disposing a reflective material on at least one side surface of the at least one semiconductor element and on at least one side surface of the dielectric filter.

23. A pixel with an optoelectronic component for generating a pixel of a display, comprising:
wherein the pixel is formed by at least two subpixels, in particular two subpixels of the same colour emission, and in particular each subpixel is formed by an optoelectronic component;
wherein a subpixel separating element is provided between two adjacent subpixels of the same pixel element; and
wherein the subpixel separating element is designed to be separating with respect to electrical control of the respective subpixels and is designed to be optically coupling with respect to the light emitted by the respective subpixels.

24. The pixel of claim 23, wherein the subpixels have a common epitaxial layer and the subpixel separation element extends trench-like into the epitaxial layer transverse to an epitaxial layer plane in a main emission direction.

25. The pixel according to claim 23, wherein the subpixels of the pixel are independently electrically contactable and/or drivable.

26. The pixel according to claim 23, wherein the at least two subpixels comprise a common active layer separated by the subpixel separation element.

27. The pixel according to claim 23, wherein the subpixel separation element extends to or at least partially through an active layer of the pixel.

28. The pixel according to claim 23, wherein the subpixel separation element is formed by quantum well intermixing generated by an in-diffused dopant, in particular in the region of the active layer.

29. The pixel according to claim 23, further comprising a lens extending over the surface of a pixel.

30. The pixel according to claim 23, wherein a transparent conductive layer is formed on a surface.

31. The pixel according to claim 23, wherein at least one contact surface for contacting at least one sub-pixel is provided on a side opposite the light emission side.

32. A display arrangement comprising a plurality of pixels according to claim 23, wherein a pixel element separation layer is provided between two adjacent pixels, the pixel element separation layer being adapted to electrically separate the adjacent pixels with respect to the driving of the respective pixels and to optically separate the adjacent pixels with respect to the light emitted from the pixels.

33. The display arrangement of claim 32, wherein the pixels and associated subpixels comprise a common epitaxial layer and the pixel element separation layer extends trench-like into the epitaxial layer transverse to the epitaxial layer plane in the main emission direction.

34. The display arrangement according to claim 32, wherein a trench depth d1 of the pixel element separation layer is greater than a trench depth of the sub-pixel separation element.

35. The display arrangement according to claim 32, wherein adjacent pixels or subpixels comprise an active layer separated by a pixel element separation layer and/or a subpixel separation element.

36. The display arrangement according to claim 32, further comprising a support layer having contact areas corresponding to contact areas of the pixels, wherein at least one of the following elements is provided in the support layer:
electrically conductive lines to a power supply of the pixel;
current driver circuits or supply circuits; and
control circuits for setting a brightness.

37-81. (canceled)
